(19) United States
(12) Patent Application Publication
(10) Pub. No.: US 2004/0132228 A1
(43) Pub. Date: Jul. 8, 2004

(54) Method and system for fabricating an OLED

(75) Inventors: John N. Magno, Middletown, NJ (US); Ilyas Khayrullin, Flanders, NJ (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 10/738,558

(22) Filed: Dec. 17, 2003

Related U.S. Application Data
(60) Provisional application No. 60/434,012, filed on Dec. 17, 2002.
(60) Provisional application No. 60/442,037, filed on Jan. 23, 2003.
(60) Provisional application No. 60/442,230, filed on Jan. 24, 2003.

(51) Int. Cl. H01L 51/40

(52) U.S. Cl. 438/99

(57) ABSTRACT

A method and system for fabricating a layer of an organic light emitting device using pulsed laser deposition is provided. A pulsed laser source is used in the method for depositing an organic or coordination complex solid sample on a substrate. A plurality of coherent light wavelengths tuned at different frequencies from the laser and directed through an optical inlet of a vacuum chamber strike a sample to form a volatized sample for depositing on a substrate. Pulsed laser sources used in the method and system include YAG, excimer, alexandrite or combinations thereof.

The system includes a pulsed laser source, a vacuum chamber, and an optical inlet for receiving at least two coherent light wavelengths tuned at different frequencies from a pulsed laser source. Alternative methods of deposition may also be performed within the same vacuum chamber.

This application claims priority from U.S. Provisional application No. 60/434,102, filed on Dec. 17, 2002; U.S. Provisional application No. 60/442,037, filed on Jan. 23, 2003; and U.S. Provisional application No. 60/442,230, filed on Jan. 24, 2003, the entire disclosures of each of which are hereby incorporated by reference herein.

### 1. FIELD OF THE INVENTION

The invention relates generally to organic light emitting devices (OLEDs) and, more particularly, to a method and system for pulsed laser deposition of an organic compound or coordination complex in fabricating an OLED.

### 2. BACKGROUND OF THE INVENTION

Tang and Van Slyke first reported on the electroluminescent properties of multi-layer devices using an organic material in 1987. C. W. Tang and S. A. Van Slyke, “Organic Electroluminescent Diodes,” Appl. Phys. Lett. 51, pp. 913-915 (1987). Various organic light emitting devices have been developed since that time. A great amount of interest has been generated due to the potential for use in a wide variety of applications.

Organic electroluminescent devices are a class of optoelectronic devices in which light emission is produced in response to an electrical current through the device. The terms “organic light emitting diode”, “organic light emitting display” or “organic light emitting device” (OLED) are commonly used to describe an organic electroluminescent device where the current-voltage behavior is non-linear. As used herein, the terms “OLED” or “OLED device” refers to this class of devices.

Unlike liquid crystal displays (LCDs) which typically require backlighting and modulate transmitted or reflected light, OLED displays are emissive devices, i.e., intense light is emitted. As a result, OLED displays are brighter, thinner, and lighter, require less space and power, offer higher contrast, and are cheaper to manufacture than LCDs. A large area display device with low-voltage driving is possible with an OLED.

In a single layer arrangement, an OLED includes an organic emissive layer, typically a spin-coated conjugated polymer, disposed between two electrodes. In a bi-layer arrangement (also referred to as single heterostructure), an OLED includes two organic layers composed of small molecules that are sequentially deposited in forming a stack structure. The two organic layers are disposed between an anode and a cathode. In the bi-layer arrangement, one of the layers is multi-functional and operates as both an emissive layer and as an electron transporting layer, or as an emissive layer and as a hole transporting layer. The other layer is a hole transporting or electron transporting layer, respectively.

In a multi-layer arrangement (also referred to as double heterostructure), an OLED includes several organic layers disposed between an anode and a cathode in the resulting stack structure. In the multi-layer arrangement, a separate emissive layer is disposed between a separate electron transport layer and hole transport layer. The separate emissive layer is typically an organic light emitting material or a mixture thereof in the form of a thin amorphous or crystalline film disposed between the hole transport layer and the electron transport layer. The emissive layer composed of an organic material can be made to electroluminesce by applying voltage across the device.

By applying voltage with sufficient amplitude and polarity to the OLED, the anode injects positive charge carriers (holes) and the cathode injects negative charge carriers (electrons), which undergo electron-hole pair recombination, radiatively decay, and in so doing, emit a photon. It should be understood by those with ordinary skill in the art that radiative decay and non-radiative decay may result in emission, or non-emission, respectively, of a photon. In a bi-layer device, the holes and electrons recombine at the interface of the emission/hole-transport layer or the emission/electron transport layer, referred to herein as a recombination zone, which can extend beyond the interface to include regions of the adjacent hole transport layer or the electron transport layer. In a multi-layer device, the holes and electrons recombine at the recombination zone of the emissive layer, which can likewise extend into adjacent and surrounding layers, such as the electron transport layer and the hole transport layer.

As the recombined excited molecules radiatively and nonradiatively decay, energy is released from the radioactive decay and emitted in the form of a photon thereby generating light, commonly referred to as electroluminescence. Electroluminescence is understood to be produced by the recombination of holes and electrons in the electron transporting layer recombination zone of a bi-layer structure, and in the separate emissive layer recombination zone of a multi-layer device. By selectively choosing the proper materials in fabricating an OLED, a significant fraction of the excitons relax (decay to ground state) and emit a photon, thereby generating light.

One of the goals in designing the arrangement and composition of the organic layers, in addition to the choice of materials for the anode and cathode, is to maximize the recombination process in the area of the emissive layer, thereby maximizing the light output from the OLED. Since the intensity is directly proportional to the current density through the device, the thin layer construction of about 1000 to about 2000 Angstroms of the bi-layer or multi-layer devices allows the device to operate with a low voltage, i.e., 2-10 V.

Forming a thin-layer film of a particular compound requires considerable effort in maintaining subtle balances between speed of deposition, temperature, and composition of active chemical components. Various methods for deposition of compounds for use in OLED fabrication are known. Those methods include thermal vapor deposition, spin coating, solvent casting, and organic vapor phase deposition (OVPD), and ink-jet printing, among other techniques. The above-mentioned processes are suitable for many compounds, however they are not universal and versatile in general. Particularly, while compounds that have a relatively low melting point (typically less than 300° C.) and low molecular weight (about 500 to 2000) can be readily evaporated via thermal vapor deposition technique, it is practically difficult or impossible to employ the same technique for polymers with a much higher molecular weight, even though they may melt at low temperatures. Similarly, even though many phosphorescent rare earth metal chelate compounds possessing great potential for OLED applications have a low melting point, they may still not be suitable for conventional thermal vacuum deposition, as the continuous thermal treatment may deleteriously lead to their decomposition.

Moreover, employing the aforementioned processes to form thin films of selected organic compounds and coordination complexes having much higher melting points (typically above 300° C. up to about 1000° C.), often proves to be difficult or impossible, or the layer formed is substantially non-uniform or rough, and unsuitable for use in an OLED. Deposition of certain organic compounds and coordination complexes using the aforementioned processes also deleteriously alters the structure of the compounds, rendering them ineffective for use in an OLED.

Desirable characteristics of an OLED include brightness, an extended operating lifetime, durability, electroluminescence efficiency, power efficiency, and a broad range of vibrant colors defined by the desired application. Attaining desirable characteristics in a multi-layer OLED device composed of different chemical compounds with all interface boundaries and doping concentrations greatly depends on the fabrication methods and processes involved, in addition to large-scale manufacturing concerns. Various desirable emission colors may not be readily obtainable due to the above limitations in fabrication and manufacturing methods. Accordingly, there remains a limited availability of compounds which provide for a full range of brilliant colors for use in an OLED.

Applications for which OLEDs are useful include displays for high performance devices, including computer displays, monitors, notebooks, and television screens, flat panel displays, general lighting elements, including, for example, instrumentation panels used in the automotive, aerospace, military, medical and other industrical applications, in addition to use as light sources, such as in bulbs, small displays for cellular phones, microdisplays for wearable computers and electronic game applications, view-finders in videocamcorders, and electronic books and newspapers, and other consumer electronics. Other uses include ink jet printing, bar code tags, digital video cameras, digital versatile disk (DVD) players, personal digital assistants (PDAs), stereos, and other personal products. OLED devices advantageously operate over a broad range of temperature conditions and over a wider viewing angle (about 160 degrees) than LCDs in the above-mentioned devices.

There remains a need for a process and system which allows the deposition of various selected organic compounds and coordination complexes suitable for use in an OLED, which compounds were heretofore unavailable for use in an OLED. There remains also a need for compounds which provide a full range of brilliant colors for use in fabricating an OLED.

### SUMMARY OF THE INVENTION

Briefly described, the present invention provides a method for fabricating an organic light emitting device (OLED) including the steps of providing a vacuum chamber, which vacuum chamber includes an optical inlet for receiving a laser beam, providing at least one pulsed laser source generating a plurality of coherent light wavelengths between about 150 nn and about 1100 nm, providing at least one retainer in the vacuum chamber for retaining an organic compound or coordination complex solid sample, disposing an organic compound or coordination complex solid sample in the retainer, providing a receiving substrate in the vacuum chamber for building an OLED upon, directing the beam including two coherent light wavelengths tuned at different frequencies from the pulsed laser source through the optical inlet to strike the solid sample to thereby form a volatized sample, and depositing the volatized sample on the receiving substrate to thereby form a layer of the OLED. The pulsed laser source used in the method of the invention is a YAG laser, excimer laser, alexandrite laser, or combination thereof. The two coherent light wavelengths strike the compound simultaneously, or may be operated at different pulse repetition rates and strike the compound at different times.

The solid sample may have a melting point from 300° C. up to 1000° C. The solid sample may be an organic compound with a melting point of less than 300° C., and is deposited without physically and chemically degrading. The solid sample may be a coordination complex with a melting point of less than 300° C., and is deposited without physically and chemically degrading. The solid sample is provided at a temperature between ambient temperature to about 77K, and is in the form of a pellet, slab or film.

According to the method, the thickness of the layer ranges between about 100-2000 Angstroms. The method may also further include the step of depositing an additional layer onto the layer formed by pulsed laser deposition using thermal-resistive evaporation, metalo-organic chemical vaporization, electron beam evaporation, and RF/DC sputtering.

According to the method, a further step includes forming a hole injection layer, forming a hole transport layer, forming an emissive layer, forming a hole blocking layer, and forming an electron injection layer. According to the method, a further step includes codepositing a host compound and at least one emissive compound with two laser sources.

According to the method of the invention, compounds that are laser deposited include preferred coordination complexes selected from: tris(4,4,4-trifluor-2-thenoyl-(1,3-butandionato-O,O′)Europium-di-(Triphenylphosphinoxide); Europate(1),tetrakis (4,4,4,-trifluoro-1-(phenyl)-1,3-butandionato-O,O′)-,hydrogen complex with N-methylmethanamine (Eu(BTA)4(NH2Me2); Europate(1-),tetrakis(4,4,4,-trifluoro-1-(2-thienyl)-1,3-butandionato-O,O′)-,ammonium; 5-[[4-dimethylamino)phenyl]methylene-2,4,6-(1H, 3H, 5H)-pyrimidinetrione; 2,6-Pyridine dicarboxylic acid europium dimethylamine complex 3:1:3; and Europium, tris(2-hydroxy-4-quinolinecarbonxylato).

Preferred organic compounds that are laser deposited according to the method of the invention are selected from 2-Naphthalenesulfonamide, N-[2-(4-oxo-4H-3,1-benzoxazin-2-yl)phenyl]; Benzenesulfonamide 4-methyl-N-[2-(4-oxo-4H-3,1-benzoxazin-2-yl)phenyl]; 2-(2-Hydroxyphenyl)-benzthiazol; 2,5-Dihydroxyterephthalic acid diethyl ester; N-(5-sodium sulfosalicoyl) anthranilic acid; 4 (1H)-Quinazolinone, 2-(5-chloro-2-hydroxyphenyl); Benzoxazol 2,2′-(2,5-thiophendiyl)-bis[5-1,1′-dimethylethyl)]; 5-[[4-(dimethylamino)phenyl]methylene]-2,4,6(1H,3H,5H)-pyrimidinetrione; and aryl benzoxazinones and quinazolinones.

A deposition system for OLED fabrication according to the invention is also provided. The system includes a laser deposition apparatus comprising a pulsed laser source generating two wavelengths for forming a layer of an OLED, a vacuum chamber comprising an optical inlet for receiving a laser beam including the two wavelengths tuned at different frequencies from the pulsed laser source, and at least one retainer for retaining a solid organic or coordination complex substance. A substrate for receiving a volatized solid organic or coordination complexes substance for forming a layer of an OLED may be provided also. The pulsed laser source used in the deposition system is a YAG, excimer, and/or alexandrite laser, and combinations thereof.

The system further may include at least one additional laser deposition apparatus for forming a co-deposited layer of an OLED within the vacuum chamber. The system may include also an alternative deposition apparatus for performing alternative techniques within the vacuum chamber, including thermal resistive evaporation, organic vapor phase deposition, electron beam evaporation, or RF/DC sputtering.

The invention also provides for an organic multilayer electroluminescent device including an anode and a cathode, which includes, therebetween, an emissive layer deposited by laser deposition according to the method of the invention.

### BRIEF DESCRIPTION OF THE DRAWINGS

The detailed description of the invention is more fully understood when read in conjunction with the FIGURES, which include:

FIG. 1a is a cross-sectional view of an OLED according to an aspect of the invention;

FIG. 1b is an exploded view of an OLED according to an aspect of the present invention;

FIG. 1c is a cross-sectional view of an OLED according to an aspect of the present invention;

FIG. 2 is a schematic view of a laser deposition system according to an aspect of the invention;

FIG. 2a is a schematic view of the system of FIG. 2, illustrating the vaporization of the sample according to an aspect of the invention;

FIG. 2b is a schematic view of the system of FIG. 2a, illustrating the deposition of a layer of an OLED according to an aspect of the invention;

FIG. 2c is a schematic view of the system of FIG. 2b, illustrating additional layers deposited to form an OLED according to an aspect of the invention;

FIG. 3 is a schematic view of a laser deposition system including a reflecting mirror according to preferred alternative embodiment of the invention;

FIG. 4 is a schematic view of a laser deposition system according to an alternative preferred embodiment of the invention;

FIG. 5 is a schematic view of a laser deposition system according to an alternative preferred embodiment of the invention;

FIG. 6 illustrates the excitation and photoluminescence (PL) spectra of Europium,tris(2-hydroxy-4-quinolinecarbonxylato) laser-deposited film according to an aspect of the invention;

FIG. 7 illustrates the excitation and photoluminescence (PL) spectra of the 2,6-Pyridine dicarboxylic acid europium dimethylamine complex 3:1:3 doped into carbazole biphenyl (CBP) by laser deposition according to an aspect of the invention;

FIG. 8 illustrates the current density vs. voltage plot for an OLED fabricated according to an aspect of the invention, where an emitter layer is ′2,2′-(1,4-phenylene)bis-4H-3,1-benzoxazinon-4-one (1,4 PPO) doped into carbazole biphenyl (CBP);

FIG. 9 illustrates the electroluminescence spectrum of an OLED fabricated according to an aspect of the invention, where an emitter layer is ′2,2′-(1,4-phenylene)bis-4H-3,1-benzoxazinon-4-one (1,4 PPO) doped into carbazole biphenyl (CBP);

FIG. 10 illustrates the current density vs. voltage plot for an OLED fabricated according to an aspect of the invention, where an emitter layer is Tris(4,4,4-trifluor-2-thenoyl-(1,3-butandionato-O,O′)Europium-di-(Triphenylphosphinoxide) (Eu(TTA)₃(TPPO)₂) doped into carbazole biphenyl (CBP);

FIG. 11 illustrates the luminance vs. voltage plot for an OLED fabricated according to an aspect of the invention, where the emitter layer of FIG. 10 is Tris(4,4,4-trifluor-2-thenoyl-(1,3-butandionato-O,O′)Europium-di-(Triphenylphosphinoxide) (Eu(TTA)₃(TPPO)₂) doped into carbazole biphenyl (CBP);

FIG. 12 illustrates the luminance vs. current density plot for an OLED fabricated to an aspect of the invention, where the OLED includes the emitter layer of FIGS. 10 and 11; and

FIG. 13 illustrates the electroluminescence spectrum of an OLED fabricated according to an aspect of the invention, where the OLED includes the emitter layer of FIGS. 10, 11 and 12.

### DETAILED DESCRIPTION OF THE INVENTION

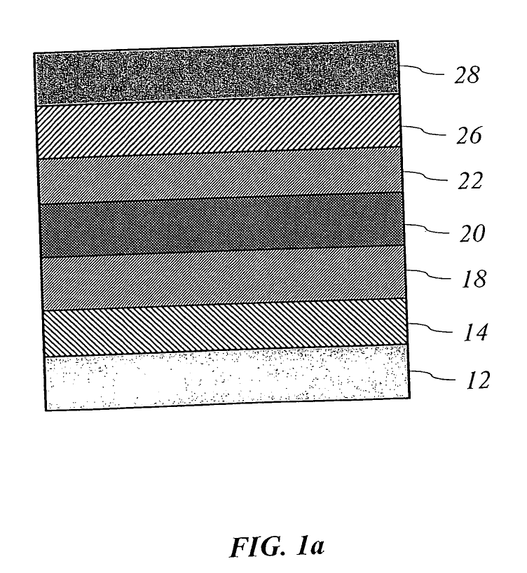

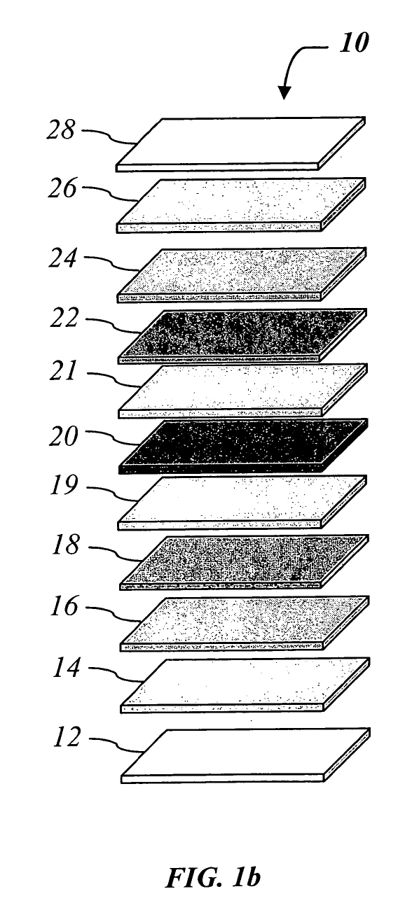

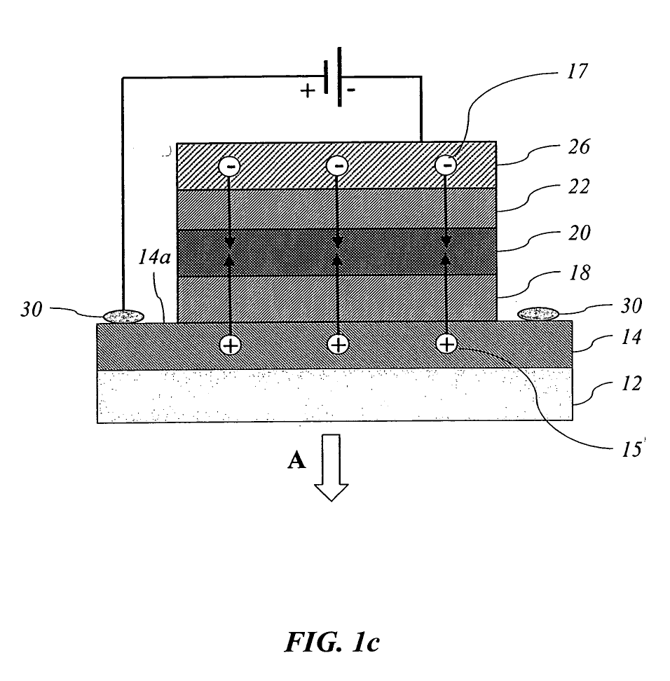

An OLED device 10 includes organic layers 14, 16, 18, 20, 22, and 24 that are sequentially deposited thereby forming a stack structure, as illustrated in FIGS. 1a and 1b. The stack may take the form of a bi-layer (single heterostructure) or a multi-layer (double heterostructure) arrangement. The functions of the organic layers are distinct and are addressed independently herein, as each may be optimized according to various desired properties, for example, obtaining a desired color or high luminance efficiency. Light emission at wavelengths ranging from about 400 nm to about 700 nm can be achieved from the OLEDs according to the invention.

It is to be understood that there may be substantial variations in the type, number, thickness, order, arrangement, and composition of the layers of an OLED device, depending upon the desired application. With regard to total device thickness, the device must be thin enough to work at low voltage. It is also to be understood that the invention is not to be limited to or bound by the theories of operation set forth herein, which are described to assist the reader in understanding the invention.

It is to be further understood that the materials used in the fabrication of an OLED device are chosen based on their respective ability to transport and inject holes, transport and inject electrons, to block the flow of electrons or holes, and to electroluminesce. The invention is not limited to any particular material, provided that the function of injecting holes, transporting holes, and injecting and transporting electrons, blocking the flow of electrons or holes, for use in a layer of an OLED is met with the material selected. Efficiency of carrier injection can be improved by choosing organic hole injection layers with a low HOMO (highest occupied molecular orbital) or a high LUMO (lowest unoccupied molecular orbital). It is to be understood that the materials used according to an aspect of the invention in the emission layer of the OLED device include all materials that luminesce by way of singlet excitation or triplet excitation, or by both excitations, i.e., fluorescence and/or phosphorescence.

The color of light emitted by the molecules depends upon the energy difference between the ground and excited states. In most organic materials, 75% of the excited molecules formed in electron-hole recombination are in a “triplet” state, while 25% are in a “singlet” state. Since the excited triplet state tends to decay to the ground state without emitting a photon, the theoretical upper limit of quantum efficiency of a fluorescent OLED is 25%. An advantage of phosphorescent OLEDs is that all excitons formed by the recombination of holes and electrons in an electroluminescent (EL) device, which are triplet-based in phosphorescent devices, participate in energy transfer and luminescence in certain electroluminescent materials. Only a small percentage of excitons in fluorescent OLED devices, which are singlet-based, result in fluorescent luminescence.

Referring to FIGS. 1a and 1c, an OLED device 10 according to an aspect of the invention preferably includes an anode layer 14 disposed onto the surface of a transparent substrate 12, a hole transport layer (HTL) 18, an emitting layer (EML) 20, an electron transport layer (ETL) 22, and a cathode layer 26. A protective layer 28 composed of glass or plastic is typically disposed adjacent the cathode layer 26, as illustrated in FIGS. 1a and 1b, to protect against oxidation and moisture, and held in place with a suitable adhesive, for example, a UV curable adhesive. The protective layer 28 may be composed of any suitable material, conductive or non-conductive. Other alternative preferred embodiments include additional layers, i.e., a hole injection layer (HIL) 16, an electron blocking layer (EBL) 19, a hole blocking layer (HBL) 21, and an electron injection layer (EIL) 24, as illustrated in FIG. 1b. As discussed above, it is to be understood that the number, arrangement, and composition of the individual layers of the device 10 may be selectively varied.

Referring to FIG. 1c, an electrical potential difference is applied between the cathode 26 and the contacts 30, for example, pogo pins plated with silver, disposed on the anode 14, whereby holes (positive charge carriers) 15 are injected by the anode 14 and migrate across the hole injection layer 16 (when present) and the hole transport layer 18 to the region of the emitting layer 20. Likewise, the electrons (negative charge carriers) 17 injected by the cathode 26 migrate across the electron injection layer 24 (when present) and the electron transport layer 22 to the region of the emitting layer 20. Injected electrons and holes are mobile, and migrate under the influence of an applied field toward the oppositely charged electrode. In this embodiment, the holes recombine with the electrons in the region of the adjacent emitting layer 20. Light is emitted in the direction of the arrow A. The potential applied to the anode 14 is higher than the potential applied to the cathode 26, and a low voltage of 2-10 V is sufficient to drive enough current to the OLED to achieve a very bright and intense light emission.

Referring to FIG. 1a, an OLED device 10 according to an aspect of the invention includes a substrate 12 composed of, for example, glass. An electrode (anode) 14 is disposed adjacent the substrate 12. Substrate 12 and the anode 14 should be transparent, i.e., the material at a selected thickness is capable of transmitting light at wavelengths emitted by the OLED device 10, and more preferably transmits substantially all of the light emitted. As used herein, a layer of material or several layers of different materials are “transparent” when the layer(s) allow for at least 50% of the ambient electromagnetic radiation in relevant wavelengths to be transmitted therethrough. Substrate 12 may also be composed of quartz, sapphire, or other suitable transparent film material, for example, rigid plastic.

Materials for the anode 14 are preferably those having a high work function. The anode 14 is typically composed of a transparent conductive material, for example, indium tin oxide (ITO), which is formed on a substrate by electron beam deposition, pulsed laser deposition, radio-frequency sputtering, or other suitable techniques. ITO is typically deposited in a high-temperature sputtering process, and is available from Thin Film Devices in New York, or may also be formed in the vacuum deposition chamber according to an aspect of the invention. When depositing on a flexible substrate in a vacuum chamber according to an aspect of the invention, RF sputtering, along with a shadow mask, is a preferred method in forming an anode pattern on the ITO. The anode should be thin enough to minimize the absorption of light, and thick enough to have low resistivity. The thickness of the deposited anode 14 is from about 200 Angstroms (Å) to 1 micron, and preferably is about 1500 Å. Thicknesses outside the above range may also be used. The ITO is subsequently patterned using any suitable technique, for example, etching in the presence of a photoresist layer to remove the resist, and other various methods to provide conductive areas and non-conductive areas which can be used in electronic circuitry. The ITO layer is then finally cleaned with O₂ plasma, radiofrequency ionic etching, or any other suitable technique. Although the anode 14 is described as transparent, it should be understood that at least one of the electrodes (cathode or anode) should be optically transparent to allow for transmission of light visible to an observer.

The anode 14, which injects holes 15 into the hole transporting layer 18, should have a high work function and an energy close to that of the HOMO levels of the hole transporting molecules. A preferred material for the anode 14 is ITO, as a source for emitting holes 15 into the HOMO levels of the hole-transporting molecules. ITO is preferred due to its high work function, i.e., a large amount of energy (4.7-5.0 eV) is required to remove an electron. Other suitable materials for emitting holes, however, may be employed in the present invention, for example, gallium indium tin oxide (GITO), and zinc indium tin oxide (ZITO).

As illustrated in FIGS. 1a and 1b, the device 10 also includes a hole transport layer (HTL) 18, and may optionally include a hole injection layer (HIL) 16. The HTL 18 is preferably disposed at a thickness ranging from about 300 to 800 Angstroms, at a rate of about 1 Å/s up to 10 Å/s, with an average rate of about 2 Å/s onto the upper surface of the anode 14. Most HTL materials are based on aromatic amines, known for their high hole mobility as compared to other organic molecules. Suitable HTL materials have a low ionization potential with a small electron affinity associated with a large energy gap. Compounds preferred for use as a hole transport layer 16 include metal phthalocyanines, such as copper phthalocyanine (CuPc), carbonyl compounds such as 1,1,4,4-tetraphenyl-1,3-butadiene (TPB), arylamines, such as N,N′-diphenyl-N,N′-bis(3-methylphenyl)-1,1′biphenyl-4,4′diamine (TPD), naphthyl-substituted benzidine derivatives, for example, 4,4′-bis[N-(1-naphthyl)-N-phenyl-amino]biphenyl (α-NPD), and N,N′-di-1-naphthyl-N,N′-diphenyl-1,1′-biphenyl-1,1′-biphenyl-4,4′-diamine (α-NPB), which compounds are available from H.W. Sands Corp., of Jupiter, Fla.

Other compounds for use as a hole transport layer include, but are not limited to N,N,N′,N′-Tetrakis(3-methylphenyl)benzidine; 1,1,4,4-Tetraphenyl-butadiene; 1,3-Bis(5-(4-diphenylamino)phenyl-1,3,4-oxadiazol-2-yl)benzene; 4,4′,4″-Tris(N-(naphthylen-2-yl)-N-phenylamino)triphenylamine; N,N′-Bis(4-methylphenyl)-N,N′-bis(phenyl)-1,4-phenylenediamine; 1,1-Bis(4-bis(4-methylphenyl)aminophenyl) cyclohexane; 4,4′-Bis(carbazol-9-yl)biphenyl; 4,4′,4″-Tris(carbazol-9-yl) triphenylamine; Poly[N-(3-methylphenyl)-N,N-diphenylamine-4,4′-diyl]; Titanium (IV) oxide phthalocyanine (amorphous/beta form); 4,4′,4″-Tris(N-3-methylphenyl-N-phenylamino)triphenylamine; 4,4′,4″-Tris(N,N-diphenylamino)triphenylamine; N,N′-Bis(naphthalen-2-yl)-N,N′-bis(phenyl)benzidine; 4-(2,2-Bisphenyl-ethen-1-yl)-4′,4″-dimethyl-triphenylamine; N,N′-Bis(3-methylphenyl)-N,N′-bis(phenyl)benzidine; 2-(4-Biphenylyl)-5-(p-tert-butylphenyl)-1,3,4-oxadiazole (sublimed); N,N,N′,N′-Tetraphenylbenzidine; 1,3-Bis[5-(4-(1,1-dimethylethyl)phenyl)-1,3,4-oxadiazol-2-yl]benzene; N,N,N′,N′-Tetrakis(4-methylphenyl)benzidine; 1,4-Bis(5-(4-diphenyl amino)phenyl-1,3,4-oxadiazol-2-yl)benzene; N,N′-Bis(4-(2,2-diphenylethen-1-yl)phenyl)-N,N′-bis(phenyl)benzidine; Poly[(N,N′-diphenyl)-N,N′-bis(p-butylphenyl)-benzidine-co-(2-Methoxy-5-(2′-ethylhexyloxy)-1,4-phenylene vinylene)]; 4,4′,4″-Tris(N-(naphthylen-1-yl)-N-phenylamino)triphenylamine; N,N′-Bis(4-methylphenyl)-N,N′-bis(phenyl)benzidine; N-(Biphenyl-4-yl)-N,N-bis(3,4-dimethylphenyl)amine; N,N′-Bis(4-(2,2-diphenylethen-1-yl)phenyl)-N,N′-bis(4-methylphenyl)benzidine; N,N′-Bis(naphthalen-1-yl)-N,N′-bis(phenyl)benzidine; N,N′-Bis(naphthalen-1-yl)-N,N′-bis(phenyl)benzidine; Tris(p-trichlorosilylpropylphenyl)amine; 4,4′-Bis-(N,N-diphenylamino)quaterphenyl; Vanadium (IV) oxide phthalocyanine; 4-(2,2-Diphenylethen-1-yl)triphenylamine; 4,4′-Bis(N-(1-naphthyl)-N-phenylamino) quaterphenyl; 2,5-Bis(4,4′-bis(N,N′-bis(4-methylphenyl)amino)phenyl)-1,3,4-oxadiazole; 1,3,5-Tris(3-methyldiphenylamino)-benzene; Poly[(N,N′-diphenyl)-N,N′-bis(p-butylphenyl)-benzidine-co-(9,9-di-n-hexylfluorene)]; and 4,4′,4″-Trismethyl-triphenylamine, all of which are available from H.W. Sands Corp.

In a bi-layer arrangement of an OLED, the HTL injects holes into the combination emission/electron transport layer, where the holes combine with electrons to form excitons. Alternatively, the electrons are injected from the ETL and combine with holes in the combination emission/hole transport layer to form excitons. In either case, the exitons are trapped in the material having the lowest energy gap. Since the ETL typically operates as an emissive layer in a bi-layer OLED, a suitable electron transport material for use in the ETL should have a lower energy gap than the HTL. In the preferred multi-layer arrangement of an OLED, holes 15 are injected from the HTL 18 and electrons 17 are injected from the ETL 22 into the region of the emissive layer 20, where they combine to form excitons. While the HTL injects holes 15 from the anode 14, it also serves to block electrons 17 injected from the cathode 26.

An optional hole injection layer (HIL) 16 illustrated in FIG. 1b is disposed adjacent the anode 14 and the HTL 18, at a thickness ranging from about 50 to 200 Angstroms, and deposited at a rate of about 1 Å/s up to 10 Å/s, with an average rate of about 2 Å/s. The HIL 16 may be composed of copper phthalocyanine (CuPc), polyaniline (PANI), or 3,4,9,10-perylentetracarboxylic dianhydride (PTCDA), although other suitable compounds may be used, such as those described with respect to the HTL 18.

The addition of an HIL 16 further improves the brightness and efficiency of the OLED device 10 by lowering the barrier controlling the injection of holes 15. The HIL 16 referably has a low ionization potential or a high HOMO level between the anode 14 and the HTL 18, which lowers the barrier for injection of holes and lowers the drive voltage. As with the HTL 18, the HIL 16 assists hole migration toward the emission layer 20.

As illustrated in FIGS. 1a, 1b, and 1c, a light emitting layer (EML) 20 is disposed adjacent ETL 22 and HTL 18. The EML 20 is disposed at a thickness ranging from about 200-500 Å at a deposition rate of about 1 Å/s, up to 10 Å/s, with an average rate of about 2 Å/s. A preferred thickness for EML 20 is about 400 Å. The EML 20 comprises a single dopant compound, or alternatively, may be formed via co-deposition of host and dopant compounds.

According to an aspect of the present invention, EML 20 comprises a single dopant material as herein described, or, alternatively comprises a host compound doped with phosphorescent or fluorescent material, including the organic compounds and coordination complexes as herein described. A preferred host material, commonly used for an EML 20, is tris(8-quinolinato) aluminum (Alq)₃. This compound produces green electroluminescence. Other preferred host materials for use in the EML 20 include, but are not limited to 2,9-dimethyl-4,7-diphenyl-1,10-phenanthroline, also referred to as bathocuproine (BCP), carbazole biphenyl (CBP), copper phthalocyanine (CuPc), and α-NPB.

Other materials for use as host material for the EML 20, available from H.W. Sands Corp., include, but are not limited to Tris[bis(4-((2-ethoxy)-2-ethoxy)ethoxy) benzoyl)methane]mono(5-minophenathroline)europium(III); Tris[bis(4-((2-ethoxy)-2-ethoxy)ethoxy)benzoyl)ethane]mono(phenathroline)europium(III); Tris(dibenzoyl-methane) mono(phenathroline disulfonicacid)europium(III) disodium salt; Tris(8-hydroxyquinolato) Gallium; Poly[(9,9-dioctylfluoren-2,7-diyl)-alt-co-(2,2′:6′,2″-terpyridin-6,6″-diyl)]; 3-(2-Benzothiazolyl)-7-diethylaminocoumarin; 1,1,4,4-Tetraphenyl-butadiene; sublimed; Poly[(9,9-dihexylfluoren-2,7-diyl)-co-(9-ethyl carbazol-2,7-diyl)];Tris(di(4-bromo)benzoylmethane) mono(phenathroline) europium(III); 9,18-Dihydro-9,18-dimethylbenzo[h]benzo[7,8]quino [2,3-b]acridine-7,16-dione; 9,18-Dihydrobenzo[h]benzo[7,8]quino[2,3-b]acridine-7,16-dione; 1,3-Bis(5-(4-diphenylamino)phenyl-1,3,4-oxadiazol-2-yl)benzene; Poly[(9,9-Dihexylfluoren-2,7-diyl)-co-(anthracen-9,10-diyl)]; 9,10-Di[9-ethyl-3-carbazovinylene)-2-methoxy-5-(2-ethylhexyloxy)benzene; Poly[(9,9-dihexylfluoren-2,7-diyl)-alt-co-(1,4-dimethylbenzen-2,5-diyl)]; Poly {[9,9-dihexyl-2,7-bis(1-cyanovinylene)fluorenylene]-alt-co-[2,5-bis(N,N′-diphenylamino)-1,4-phenylene]}; Poly(9,9-dihexyl-2,7-(2-cyanovinylene)fluorenylene); Poly[(9,9-dioctylfluoren-2,7-diyl); Poly[(9,9-dihexylfluoren-2,7-diyl)-alt-co-(pyridin-3,5-diyl)]; Poly[(9,9-Dioctyl-2,7-bis(2-cyano)vinylenefluorenylene)-alt-co-(2-methoxy-5-(2-ethylhexyloxy)-1,4-phenylene)]; Poly[(9,9-dihexylfluoren-2,7-diyl)-alt-co-(benzen-1,4-diyl)]; Poly[(2-methoxy-5-(2′-ethylhexyloxy)-1,4-phenylenevinylene)-co-(4,4′-biphenyl-enevinylene)][0.8/0.2]; Poly[(9,9-dioctylfluoren-2,7-diyl)-alt-co-(2,2′-bipyridin-6,6′-diyl)]; Poly{[9-ethyl-3,6-bis(2-cyanovinylene)carbazolyene-alt-co-[2-methoxy-5-(2′-ethylhexyloxy)-1,4-phenylene}; Poly[N-(3-methylphenyl)-N,N-diphenylamine-4,4′-diyl]; Tris(dibenzoyl-methane) mono(4,7-diphenylphenathroline)europium (III); Tris(hexa fluoroacetylacetonate)mono(1,10-phenanthroline) erbium (III); Poly[(9,9-dihexyl)fluoren-2,7-diyl)-alt-co-(9,9-di-(5-pentenyl)-fluorenyl-2,7-diyl)]; 7,16-Dihydro-7,16-dimethylbenzo-[a]benzo[5,6]quino[3,2-I]acridine-9,18-dione; Bis-(2-methyl-8-quinolinolato)-4-(phenylphenolato)-aluminium-(III); Poly[(9,9-dihexylfluoren-2,7-diyl)-alt-co-(9,9′-spirobifluoren-2,7-diyl)]; Poly{[2-methoxy-5-(2-ethylhexyloxy)-1,4-bis(1-cyanovinylene)phenylene)]-alt-co-[2,5-bis(N,N′-diphenylamino)-1,4-phenylene]}; Tris(dibenzoylmethane) mono(4,7-dimethylphenathroline)europium (III); Diphenyl-borane-8-hydroxyquinolate; 2,3,5,6-1H,4H-Tetrahydro-8-trifluormethylquinolizino-(9,9a,1-gh)coumarin; Poly[(9,9-dioctylfluoren-2,7-diyl)-alt-co-(2,5-dimethoxybenzen-1,4-diyl)]; Poly[(9,9-dioctylfluoren-2,7-diyl)-alt-co-(2,5-dimethoxybenzen-1,4-diyl)]; Tris(1,10-Phenanthrolene) ruthenium (II) chloride; 9,10-Di[9-ethyl-3-carbazoyl)-vinylene)]-anthracene; Poly[(9,9-dihexylfluorenyl-2,7,diyl)-co-(N,N′bis {p-bytulphenyl}-1,4-diaminophenylene)]; Poly[2-Methoxy-5-(2′-ethylhexyoxy)-1,4-phenylenevinylene-co-4,4′-bisphenylenevinylene]; 2-(4-Biphenylyl)-5-(p-tert-butylphenyl)-1,3,4-oxadiazole (sublimed); Poly[(9,9-dioctylfluoren-2,7-diyl)-co-(ethylynylbenzene)]; Tris(dinaphthoyl-methane) mono(phenathroline)europium (III); Lithium Tetra(8-hydroxyquinolinato)-boron; 1,3-Bis[5-(4-(1,1-dimethylethyl)phenyl)-1,3,4-oxadiazol-2-yl]benzene; Tris(8-hydroxyquinoline) erbium; Tetra(2-methyl-8-hydroxyquinolato)boron, lithium salt; Tris(benzoyltrifluoroacetonato)europium (III); 4-(Dicyanomethylene)-2-methyl-6-(julolidin-4-yl-vinyl)-4H-pyran; Tris(benzoyltrifluoroacetonate) mono(1,10-phenanthroline) erbium (III); Poly[(9,9-dioctylfluoren-2,7-diyl)-co-(1,4-diphenylene-vinylene-2-methoxy-5-{2-ethylhexyloxy}benzene)]; Tris-(5-chloro-8-hydroxy-quinolinato)-aluminium; 2,3,7,8,12,13,17,18-Octaethyl-21H,23H-porphine platinum (II); 1,4-Bis(5-(4-diphenylamino)phenyl-1,3,4-oxadiazol-2-yl)benzene; Tris(biphenoyl-methane) mono(phenanthroline)europium (III); Poly[(9,9-dihexylfluoren-2,7-diyl)-co-(N,N′-di(4-butylphenyl)-N,N′-diphenyl-4,4′-diyl-1,4-diaminobenzene)]; Bis(8-hydroxyquinolinato)zinc; Tris(4-methyl-8-hydroxyquinoline)aluminum; 2,3,5,6-1H,4H-Tetrahydro-8-methoxycarbonyl-quinolizino-(9,9a, 1-gh)coumarin; Poly[(9,9-Dioctyl-2,7-divinylenefluorenylene)-alt-co-(anthracen-9,10-diyl)]; Tris[2-(2-pyridinyl)phenyl-C,N]-iridium; N,N′-Bis(4-(2,2-diphenylethen-1-yl)phenyl)-N,N′-bis(phenyl)benzidine; Poly[(N,N′-diphenyl)-N,N′-bis(p-butylphenyl)-benzidine-co-(2-Methoxy-5-(2′-ethylhexyloxy)-1,4-phenylenevinylene)]; N,N′-Dimethylquinacridone; Poly[(9,9-Dioctyl-2,7-divinylenefluorenylene)-alt-co-(2-methoxy-5-(2-ethylhexyloxy)-1,4-phenylene)]; Poly[(9,9-dihexylfluoren-2,7-diyl)-alt-co-(2-methoxy-5-{2-ethylhexyloxy}phenylen-1,4-diyl)]; Tris(5,7-dichloro-8-hydroxyquinolinato)-aluminium; Bis(2-methyl-8-hydroxyquinolinato)zinc; N,N′-Bis(4-(2,2-diphenylethen-1-yl)phenyl)-N,N′-bis(4-methylphenyl)-benzidine; N,N′-Bis(4-(2,2-diphenylethen-1-yl)phenyl)-N,N′-bis(phenyl)benzidine; Poly[(N,N′-diphenyl)-N,N′-bis(p-butylphenyl)-benzidine-co-(2-Methoxy-5-(2′-ethylhexyloxy)-1,4-phenylenevinylene)]; N,N′-Dimethylquinacridone; Poly[(9,9-Dioctyl-2,7-divinylenefluorenylene)-alt-co-(2-methoxy-5-(2-ethylhexyloxy)-1,4-phenylene)]; Poly[(9,9-dihexylfluoren-2,7-diyl)-alt-co-(2-methoxy-5-{2-ethylhexyloxy}phenylen-1,4-diyl)]; Tris(5,7-dichloro-8-hydroxyquinolinato)-aluminium; Bis(2-methyl-8-hydroxyquinolinato)zinc; N,N′-Bis(4-(2,2-diphenylethen-1-yl)phenyl)-N,N′-bis(4-methylphenyl)benzidine; 1-(2,2-Diphenylethen-1-yl)pyrene; Tris(4,7-diphenyl-1,10-phenanthroline) ruthenium (II) chloride; Tris(4,7-diphehyl-1,10-phenanthroline) ruthenium (II) chloride; 4,4′-Bis(2,2-diphenylethen-1-yl)biphenyl; N,N,N′,N′-Tetrakis-(naphth-2-yl)benzidine; 4-(Dicyanomethylene)-2-methyl-6-(p-dimethylaminostyryl)-4H-pyran; N,N′-Bis(phenanthren-9-yl)-N,N′-diphenylbenzidine; Tris(benzoylacetonato)-mono(phenanthroline)europium(III); 4,4′-Bis(dihydro-dibenzazepin-1-yl)biphenyl; 4-(2,2-Diphenylethen-1-yl)triphenylamine; 4,4′-Bis(dibenzazepin-1-yl)biphenyl; 4,4′-(Bis(9-ethyl-3-carbazovinylene)-1,1′-biphenyl; Tris(1-phenyl-3-methyl-4-(2,2-dimethylpropan-1-oyl)-pyrazolin-5-one)terbium (III); Poly[2-(6-Cyano-6-methylheptyl-oxy)-1,4-phenylene]; 2,5-Bis(4,4′-bis(N,N′-bis(4-methylphenyl)amino)phenyl)-1,3,4-oxadiazole; Tris(4,7-diphenyl-1,10-phenanthroline) ruthenium (II) perchlorate; Tris(2,2′,2″-terpyridine) ruthenium (II) chloride; Poly[(9,9-dihexylfluoren-2,7-diyl)-alt-co-(N,N′-bis(4-butylphenyl)benzidine-N,N′-diphenylen-1,4′-diyl)]; Poly[(9,9-dihexyl-fluoren-2,7-diyl)-alt-co-(N,N′-bis(4-butylphenyl)benzidine-N,N′-diphenylen-1,4′-diyl)]; Poly[2-Methoxy-5-(2′-ethylhexyloxy)-1,4-(1-cyanovinylene)phenylene]; Poly[(9,9-Dioctyl-2,7-divinylenefluorenylene)-alt-co-(biphenyl-4,4′-diyl)]; Tris(dibenzoylmethane) mono(5-aminophenanthroline)europium (III); N,N-Diphenylquinacridone; Poly[2-Methoxy-5-(2′-ethylhexyloxy)-1,4-phenylenevinylene]; Poly(9,9-di-n-hexylfluorenyl-2,7-diyl); Tris(dibenzoylmethane) mono(phenanthroline)europium (III); Poly[(9,9-dihexylfluoren-2,7-diyl)-alt-co-(benzo[2,1,3]thiadiazol-4,7-diyl)]; Tris(2,2′-bipyridine) ruthenium (II) chloride; Poly[9,9-di-(2-ethylhexyl)fluoren-2,7-diyl]; Poly[(9,9-di-n-octylfluoren-2,7-diyl)-co-(1,4-vinylenephenylene)]; and [Poly[(9,9-di-n-octylfluoren-2,7-diyl)-co-(1,4-vinylenephenylene)].

Materials present as host and dopant, particularly in the EML 20, are selected to have a high level of energy transfer between the host and dopant molecules. The term “host” is used to refer to the compound in the emissive layer 20 which receives the hole/electron recombination energy. Through an emission/absorption energy transfer process, the excitation energy of the host is then transferred to the dopant emitter compound, which is typically present in a lower concentration than the host compound. The dopant emitter compound may then relax to an excited state having a slightly lower energy level, which preferentially radiates all of the energy as a luminescent emission in a desired spectral region. The host compound can have a strong emission in a region of the spectrum where the dopant strongly absorbs light, but the host preferably does not have an emission band in a region where the dopant also emits strongly.

The use of host/dopant combinations extends the range of colors emitted by the OLED device 10. Incorporating various dopants into the host compound improves the performance of the device 10, including efficiency and luminance of the host EML 20. The concentration of the dopant depends upon the desired application, and is not restricted to any particular range. An effective amount of dopant present is an amount sufficient to shift the emission wavelength of the host. It is preferred, however, that the concentration of the dopant range from about 0.01 to 10.0 mol %. A preferred amount is 0.1 to about 1.0 mol %, depending upon the host emitting material used. If the dopant concentration is too low, the emission will include a component of light from the host compound. If the dopant concentration is too high, emission efficiencies can be adversely affected by self-quenching, a non-emissive mechanism. Although dopants are described herein for use in the EML 20, they may be used also in the emissive/electron transport layer of a bi-layer device. A host/dopant combination may be present also in other layers of the OLED device 10. Also, the dopants described herein may be used solely as a separate layer of the OLED device 10.

Dopants for use in the present invention, particularly in the EML 20, include compounds exhibiting phosphorescence and fluorescence. Examples of phosphorescent dopant materials are organic phosphorescent dyes including coumarin, dicyanomethylene pyranes, polymethine, oxabenzanthrane, xanthene, pyrylium, carbostyl, quinacridone, rubrene, coronene, phenanthrecene, pyrene, butadiene, stilbene, and derivatives thereof, disclosed in U.S. Pat. No. 6,392,250 to Aziz, the entire disclosure of which is hereby incorporated by reference. Examples of fluorescent dyes used as dopants include perylene, anthracene, butadienes, and derivatives thereof.

As used herein, the term “coordination complex” refers to a compound having a central metal atom or atoms for which one or more organic moieties are coordinated. The metal may comprise a main group or rare earth element. The coordinated moieties may be an inorganic compound, for example, an ammonium, phosphate, or carbonyl moiety.

Preferred coordination complexes for use as dopants include, for example, europium-ammonium chelates, disclosed in U.S. patent application Ser. No. 10/226,833, filed on Aug. 23, 2002, titled Europium-Ammonium Tetra Chelates, assigned to the assignee herein, the entire disclosure of which is hereby incorporated by reference.

Preferred coordination complexes for use as dopants in the present invention also include other europium chelate complexes, such as tris(4,4,4-trifluor-2-thenoyl-(1,3-butandionato-O,O′)Europium-di-(Triphenylphosphinoxide) (Eu(TTA)₃(TPPO)₂), having a melting point of 250° C.; Europate(1),tetrakis(4,4,4,-trifluoro-1-(phenyl)-1,3-butandionato-O,O′)-,hydrogen, comp. with N-methylmethanamine Eu(BTA)₄(NH₂Me₂), having a melting point of 178° C.; Europate(1-),tetrakis(4,4,4,-trifluoro-1-(2-thienyl)-1,3-butandionato-O,O′)-,ammonium (Eu(TTA)₄NH₄), having a melting point of 175° C.; 5-[[4-dimethylamino)phenyl]methylene-2,4,6-(1H, 3H, 5H)-pyrimidinetrione (DMAPMPT), having a melting point of 270° C., 2,6-Pyridine dicarboxylic acid europium dimethylamine complex 3:1:3 (Eu(DPA)₃(NH₂Me₂)₃), having a melting point of greater than 300° C.; and Europium, tris(2-hydroxy-4-quinolinecarbonxylato)-(Eu(2-HQC)₃ having a melting point of greater than 400° C., all of which are disclosed in U.S. Provisional application Serial No. 60/442,230, filed on Jan. 24, 2003, titled Benzoxazinone and Quinazoline Derivatives, assigned to the assignee herein, the entire disclosure of which is hereby incorporated by reference.

Preferred organic dopants for use in the present invention include 2-Naphthalenesulfonamide, N-[2-(4-oxo-4H-3,1-benzoxazin-2-yl)phenyl]-(NBP), having a melting point of 186° C.; 2-Naphthalenesulfonamide, Benzenesulfonamide, 4-methyl-N-[2-(4-oxo-4H-3,1-benzoxazin-2-yl)phenyl]-(TosBP) having a melting point of 215° C.; 2-(2-Hydroxyphenyl)-benzthiazol (2-HPBT) having a melting point of 133° C.; 2,5-Dihydroxyterephthalic acid diethyl ester (DHTADE), having a melting point of 134° C.; N-(5-sodium sulfosalicoyl) anthranilic acid (NaSSAA), having a melting point of 300° C.; 4 (1H)-Quinazolinone, 2-(5-chloro-2-hydroxyphenyl)-(2-HPCIQ), having a melting point of 375° C.; Benzoxazol 2,2′-(2,5-thiophendiyl)-bis[5-1,1′-dimethylethyl)] (TPBBO) having a melting point of 200° C.; and 5-[[4-(dimethylamino)phenyl]methylene]-2,4,6(1H,3H,5H)-pyrimidinetrione, having a melting point of 270° C.

Preferred organic dopants also include aryl benzoxazinones and quinazolinones, for example, 2,2-[1,4-phenylene]-bis-4H-3,1-benzoxazin-4-one (1,4 PPO). Other organic dopants include 2,2′-(1,4-naphthaylene)bis-4H-3,1-benzoxazin-4-one; [2,2′]bi-benz[d][1,3]oxazinyl]-4,4′-dione; 2,2′,2″-(1,3,5-phenylene)tris-4H-3,1-benzoxazin-4-one; 2,2′-(1,5-pyridyl)bis-4H-3,1-benzoxazin-4-one; 2,2′-(1,3-phenylene)bis-4H-3,1-benzoxazin-4-one; 2,2′-(1,4-naphthylene)bis-4H-3,1-benzoxazin-4-one; 2,2′-(1,4-phenylene)-2,3,5,6-(tetrafluoro)-bis-4H-3,1-benzoxazin-4-one; 3H, 3′H-[2,2′]-1,4-phenylene-bis-quinazolin-4-one; 2,2′-(1,4-pyridyl)bis-4H-3, 1-benzoxazin-4-one; 2,2′-(1,4-phenylene-2,5-diacetoxy)-bis-4H-3,1-benzoxazin-4-one; 2,2′-(1,4-phenylene-2,5-dihydroxy)bis-4H-3,1-benzoxazin-4-one; 3H, 3′H-[2,2′]-biquinazolinyl-4,4′-dione; and 2,2″-(4,4″-biphenylene)bis-4H-3,1-benzoxazinone.

Organic compounds may also include: tris-(8-hydroxyquinoline)aluminum (Alq₃), 2-(4-biphenyl)-5-(4-tert-phenyl)-1,3,3-oxadiazole (PBD), N,N′-diphenyl-N,N′-bis-(3-methylphenyl)-(1,1′-biphenyl)-4,4′-diamine (TPD), N,N′-diphenyl-N,N′-di(m-tolyl)benzidine (TPD), 2-(4-biphenyl)-5-(4-tert-butylphenyl)-1,3,4-oxydiazole(PBD), N,N′-bis-2,5-di-tertbutylphenyl)-3,4,9,10-perylenedicarboximide (BPPC), 4,4′,4″-(tris(3-methylphenylphenylamino) triphenylamine (TAD), 1,2,3,4,5-pentaphenyl-1,3-cyclopentadiene (PPCP), bis-(triphenyl)diamine (TAD), 1,2,4-triazole(p-etTAZ), 2-napthyl-4,5-bis-(4-methoxyphenyl)1-3-oxazole (NAPOXA), perylene bisimide pigment (PBP), tris-1-(phenyl-3-methyl-4-isobutyl-5-pyrozolone-bis-(triphenyl phosphine oxide)terbium (PTT), 2,9-dimethyl-4,7-diphenyl-1,10-phenan-throline (BCP), 4,4″-N,N′-dicarbazole-biphenyl (CBP), 4,4′-bis[N-(1-napthyl)-N-phenyl-amino]biphenyl (α-NPD), 3-phenyl-4-(1′napthyl)-5-phenyl-1,2,4-triazole (TAZ), 3-(4-biphenylyl)-4-phenyl-5-tert-butylphenyl-1,2,4-triazole (TAZ), 4,4′-bis[N,N′-(3-tolyl)amino]-3,3′-dimethyl-biphenyl (HMTPD), copper phthalocyanine, 4-dicyanomethylene-2-methyl-6-[2-(2,3,6,7-tetrahydro-1H, 5H-benzo[ij]quinolizin-8-yl)-4H-pyran (DCM2), [2-methyl-6-[2-(2,3,6,7-tetrahydro-1H, and 5H-benzo[ij]quinolizin-9-yl)ethenyl]-4H-pyran-4-ylidene}propane-dinitrile (DCM2).

Additional coordination complexes include: 2-(o-hydroxyphenyl)benzothiazole Zn complex I, [tris-(4,4,4-trifluoro-1-(2-thienyl)-butane-1,3-dionate)-triphenyl phosphine oxide europium (III)] (Eu(TTA)₃(TPPO), platinum octaethylporphine (PtOEP), 2,3,7,8,12,13,17, 18-octaethyl-21H, 23H-porphine platinum(II) (PtOEP), tris(2-phenylpryidine) iridium, europium thenoyltrifluoroacetone-1,10-phenanthroline (Eu(TTA)₃phen), bis-(2-(2′-benzo[4,5-a]thienyl) pyridinato-N,C3′) iridium (acetyl-acetonate) [btp2Ir(acac)], fac tris(2-phenylpyridine) iridium (Ir(ppy)₃); and terbium tris-(1-phenyl-3-methyl-4-(trimethylacetyl)pyrazol-4-one) triphenylphosphine-oxide [(tb-PMP)₃Tb(Ph₃PO).

Other coordination complexes include phosphorescent materials, for example, heavy metal complexes such as platinum octaethylporphine (PtOEP), disclosed in U.S. Pat. No. 6,303,238 to Thompson, the entire disclosure of which is hereby incorporated by reference, and iridium complexes such as Tris[2-(2-pyridinyl)phenyl-C,N]-iridium; Tris(2-phenylpyridine) iridium (III) (Ir(ppy)₃), disclosed in U.S. Pat. No. 6,392,250 to Aziz, and in Baldo et.al., “Highly efficient organic phosphorescent emission from organic electroluminescent devices”, Letters to Nature, 395, pp 151-154 (1998), the entire disclosures of which are hereby incorporated by reference. Preferred examples include 2,3,7,8,12,13,17,18-octaethyl-21H23H-phorpine platinum(II) (PtOEP) and fac tris(2-phenylpyridine)iridium Ir(ppy)₃).

A preferred embodiment of the emitting layer 20 according to an aspect of the invention comprises a host compound (CBP) doped with an organic compound or coordination complex, such as 2,2-[1,4-phenylene]-bis-4H-3,1-benzoxazin-4-one; N-(5-sodium sulfosalicoyl)anthranilic acid; 4(1H)-quinazolinone, 2-(5-chloro-2-hydroxy-phenyl); tris-(4,4,4-trifluor-2-thenoyl-(1,3,-butandionato-O-O′)Europium-di-(triphenyl-phosphinoxide); Europium, tris(2-hydroxy-4-quinolinecarbonxylato); and 2,6-pyridine dicarboxylic acid europium dimethylamine complex 3:1:3.

The invention is not limited to any particular ratio of dopant to host. It should be understood that the ratio of dopant to host varies depending upon the particular application. To achieve a 4% doping level, for example, the deposition rate for the host is maintained at about 9.6 Å/s, and the rate for the dopant is maintained at about 0.4 Å/s. This particular method of deposition achieves a weight ratio of 4:96 for the dopant and host, respectively. The description of deposition rate and thickness herein is for illustration purposes, and should not be construed as limiting as to the particular ratio, speed of deposition, or compounds described. Advantageously, the dopant material or materials may be deposited or codeposited, respectively, with a host compound using pulsed laser deposition, according to an aspect of the present invention.

Although a dopant and or host may emit in a particular wavelength, the color emitted by the OLED device 10 can be shifted by using a particular dopant or host. For example, the host compound may be CBP, which emits a blue light. If the host layer of CBP is doped with a suitable amount of tris-(4,4,4-trifluor-2-thenoyl-(1,3,-butandionato-O-O′)Europium-di-(triphenylphosphinoxid), the OLED device will emit a red light. Thus, by selectively doping the host compound with a dopant or a plurality of dopants capable of shifting the wavelength of a host, the wavelength of the emissive layer is shifted. It is to be understood that dopants capable of shifting the wavelength of an emissive layer should be present in an amount effective to shift the wavelength to a desired color. Since the color of the light emitted by the molecules depends upon the energy difference between the ground and excited states, the color of the emitted light and the electrical characteristics of the OLED depend upon the specific organic material(s) used. In addition to shifting the emission color of the EML 20, other layers of the OLED device 10 may be doped to achieve changes in emission color or to improve device performance, including efficiency and stability, for example, improving conductivity.

The addition of an electron transport layer (ETL) 22 which is disposed adjacent the cathode 26 and the EML 20 lowers the current density level and also the drive voltage used to operate the device. Compounds described above for use as the EML 20 may also be used in forming an ETL 22. For example, metal chelates of 8-hydroxyquinone, including (Alq₃), are preferred electron transport materials. The ETL 22 is deposited with a thickness ranging from about 300 to 500 Angstroms, at a deposition rate of about deposition rate of about 1 Å/s, up to 10 Å/s, with an average rate of about 2 Å/s. A preferred thickness for an EML 20 is about 300 Å to about 500 Å. Thicknesses outside the stated range may also be suitable, depending upon the application.

The device also may optionally include an electron injection layer (EIL) 24 disposed adjacent the ETL 22. The EIL 24 functions to improve injection of electrons from the cathode 26 to the ETL 22. A typical EIL 24 is composed of lithium-fluoride or a calcium compound. The EIL 24 may also comprise any known conventional electron transmitting compound, such as those described herein with regard to the EML 20, and also includes, but is not limited to triazole derivatives, oxazole derivatives, oxadiazole derivatives, fluorenone derivatives, anthraquinodimethane derivatives, anthrone derivatives, diphenylquinone derivatives, thiopyran dioxide derivatives, carbodiimide derivatives, fluorenylidenemethane derivatives, distyrylpyrazine derivatives, heterocyclic tetracarboxylic anhydrides such as naphthaleneperylene, phthalocyanine derivatives, and various metal complexes represented by metal complexes of 8-quinolinol derivatives, metallophthalocyanine, and metal complexes each having benzoxazole or benzothiazole as a ligand, described in U.S. Pat. No. 6,461,747 to Okada, the entire disclosure of which is hereby incorporated by reference. The thickness of the EIL 24 ranges between about 5 to 20 Å, and is disposed at a deposition rate of about 0.1 Å/s, up to 1 Å/s, with an average rate of about 0.5 Å/s. A preferred thickness is about 10 Å. Thicknesses outside this range may also suitably be used.

The device 10 may also optionally include an electron blocking layer (EBL) 19 and hole blocking layer (HBL) 21. Compounds for use as a HBL 21 include CBP and BCP, in addition to 3,4,5-triphenyl-1,2,4-trizole, 3-(biphenyl-4-yl)-4-phenyl-5-tert-butylphenyl-1,2,4-triazole, 3,5,-bis(4-tert-butylphenyl)-4-phenyl-[1,2,4]triazole, and 2,9-dimethyl-4,7-diphenyl-1,10-phenanthroline, all available from H.W. Sands. Compounds for use as a EBL 19 include TPD.

Materials for the cathode are preferably those having a low work function. A metallic cathode 26, composed of, for example, aluminum, or magnesium and silver, is disposed adjacent the electron injection layer 24. A cathode 26 composed of Al or Mg:Ag, at a ratio of 10:90, respectively, is preferred for use in the present invention. Since the cathode 26 is needed to inject electrons into the LUMO level of the electron-transporting layer(s), material(s) with low work function, for example, from about 3.5 eV to about 4.0 eV, and preferably from about 3.5 eV to about 3.7 eV are used to enhance quantum efficiency. The thickness of the cathode 26 ranges, for example, from about 1000 Angstroms to about 2000 Angstroms. A preferred thickness is about 1500 Angstroms. Thicknesses outside this range may also suitably be used. A protecting layer 28 is also preferably disposed onto the surface of the cathode 26 to protect the device 10 from humidity and environmental conditions.

The OLED devices 10 according to the invention advantageously may be fabricated entirely within a vacuum system using pulsed laser deposition, in combination with other deposition techniques known in the art, without removing the OLED device 10 from the vacuum chamber during fabrication. In many instances, due to the high melting point of the materials described herein, the organic compounds and coordination complexes cannot be deposited by other methods without destroying the structure of the compounds. In other instances, the compound or complex deposited according to the invention may have a melting point below 300° C., but will otherwise thermally degrade using conventional deposition techniques. Co-deposition of several compounds may also take place within the vacuum system according to the invention by the addition of a second or a third pulsed laser source, directed upon at least two different compounds disposed within the chamber, or alternatively upon a sample containing at least two different compounds.

Coordination complexes such as europium chelates often have a significantly high melting temperature and thus represent an extremely difficult case for using the conventional method of vapor deposition typically used in fabricating an OLED. For example, it is practically impossible to evaporate europium tris (2-hydroxy-4-quinolinecarbonxylato) complex, which has melting temperature in the range of 395-405° C. by heat-resistive evaporation. The present invention demonstrates that high quality films can be formed by pulsed laser deposition according to the methods herein described. For example, a coordination complex, 2,6-Pyridine dicarboxylic acid europium dimethylamine complex 3:1:3 Eu(DPA)₃(NH₂Me₂)₃ may be deposited using a laser without destroying the structure of the Eu(DPA)₃(NH₂Me₂)₃.

A pulsed laser providing a source for a pulsed laser beam is preferred for use in the method and system of the present invention, both for high melting point materials, and for materials with a lower melting point, since less material is consumed in the process compared to other known processes. A more uniform layer also results using a pulsed laser. Pulsed lasers are commercially available within the full spectral range from UV to IR. These lasers typically emit light having a wavelength ranging from about 157 nm to 1100 nm, preferably from 250 to 1050 nm, an energy density of about 0.05 to 10 J/cm², a pulsewidth of about 10⁻¹² to 10⁻⁶ per second, and a pulse repetition frequency of about 0 Hz to greater than 20,000 Hz. Examples of suitable lasers include, but are not limited to pulsed gas lasers, such as an excimer laser, i.e., F2 (157 nm), ArF (193 nm). KrF (248 nm), XeCl (308 nm), and XeF (351 nm). Other suitable lasers include pulsed solid state lasers, such as YAG (457-1040 nm), and Alexandrite (380 nm to 760 nm). Preferred lasers for use in the present invention include an Alexandrite laser, disclosed in U.S. Pat. Nos. 3,997,853; 4,272,733; 4,734,913; 4,809,283; 4,835,786; 4,858,242; 4,933,946; 4,944,567; 4,949,346; 5,009,658; 5,321,711; and 5,331,652, the disclosures of which are hereby incorporated by reference, an XeCl laser LPX200, manufactured by Lambda Physik of Gottingen, Germany, and YAG lasers.

While the mechanism of the laser deposition process for every particular class of material is yet to be understood, it is evident in the present embodiment that simultaneous treatment of an organic compound or coordination complex with both short and long wavelength laser beams results in a better quality film. It is to be understood that the effectiveness of the laser deposition process of the present invention regarding any given organic compound or coordination complex greatly depends on the combination of two (or three) laser frequencies, pulse durations and repetition rates, the radiation energy delivered upon surface of the compound, and other factors known to those skilled in the art.

In a preferred embodiment, a first laser source provides for pulsed coherent radiation in two wavelengths, i.e., short and long. The two wavelength pulses in phase operating at the same pulse repetition rate are administered simultaneously. It is to be understood that a short wavelength is generally less than 600 nm and a long wavelength is generally greater than 600 nm.

In an alternative preferred embodiment, the laser source provides coherent radiation in two wavelengths, but the two wavelengths operate at different pulse repetition rates, and are not in phase. Thus, each wavelength strikes the solid sample at different times.

In an alternative preferred embodiment, a second laser source is provided, which operates in phase with at least one of the wavelength pulses from the first laser source at the same pulse repetition rates, and all three wavelength pulses are different. In yet a further alternative preferred embodiment, the second laser source generates a wavelength pulse that operates at a different pulse repetition rate, and is not in phase with any of the wavelength pulses from the first laser source, and all three wavelengths are different. In this alternative preferred embodiment, at least one of the beams of the wavelengths strikes the solid sample at a different time than the other beam of the other wavelengths. It is to be understood by those skilled in the art that the duration of the laser emission depends upon the material and the laser used.

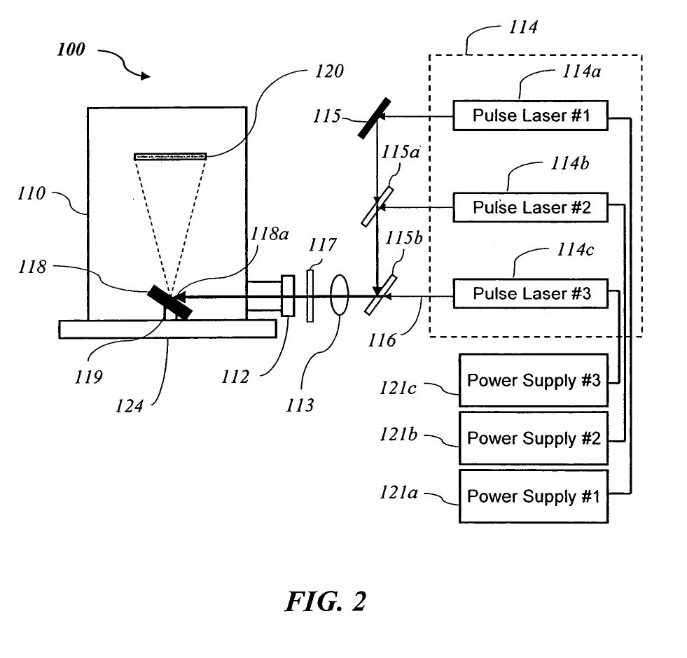

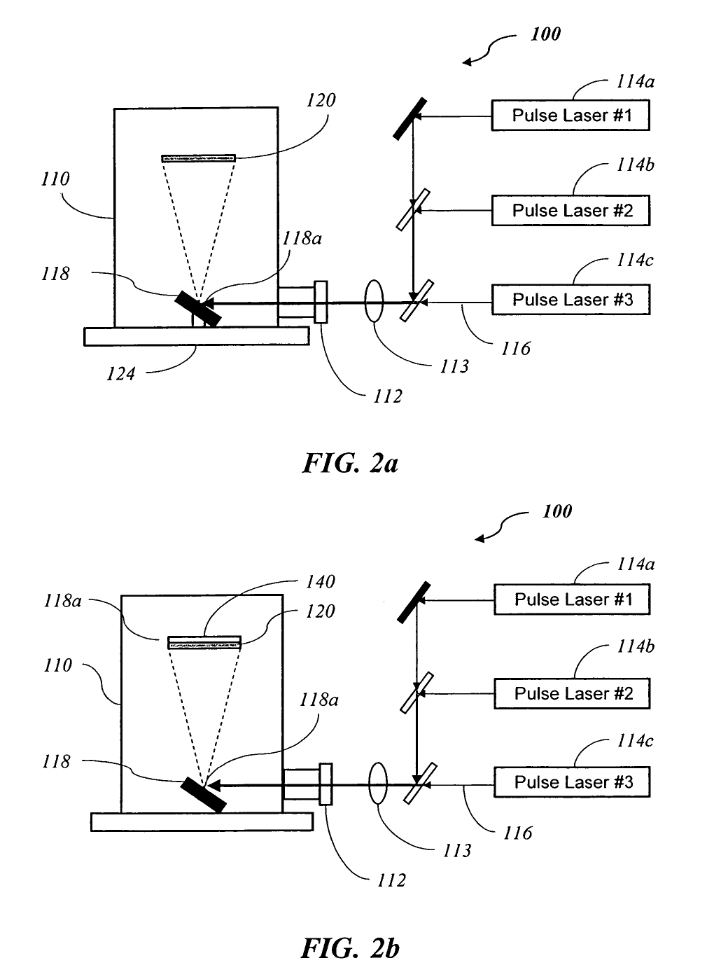

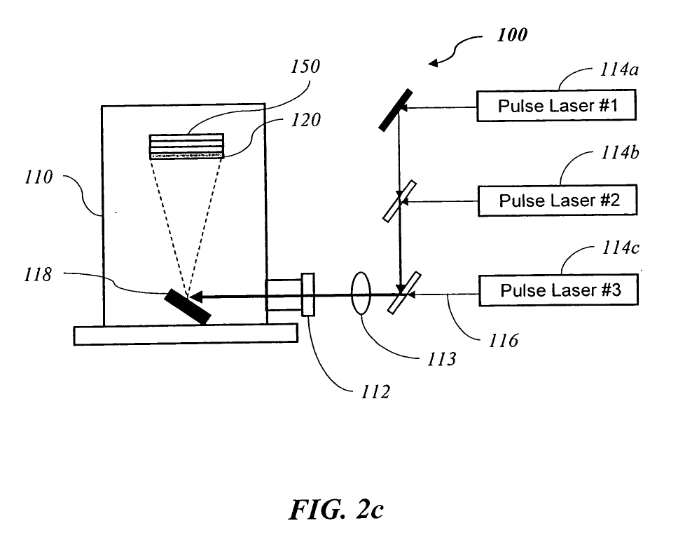

Referring to FIG. 2, a laser deposition system 100 according to an aspect of the invention is illustrated. Laser deposition system 100 includes a vacuum chamber 110 disposed on a bottom plate 124, and an optical inlet 112 for receiving a laser beam 116 into the chamber 110 through focusing lens 113. At least one laser source 114a, preferably a pulsed laser, is disposed adjacent the vacuum chamber 110, which laser source 114a generates a laser beam 116 via power supply 121a. Preferably, a combined laser source 114 comprised of a plurality of laser sources 114a, 114b, and/or 114c, simultaneously generates laser radiation both at short and long wavelengths and at different pulse frequencies, via power supplies 121a, 121b, and 121c. All laser beams emitting from laser sources 114a, 114b, and 114c of the combined laser source 114 in the various embodiments of the invention are collected by means of mirror 115 and semitransparent mirrors 115a and 115b into laser beam 116 and directed into focusing lens 112. An optical steering device 117 is placed between focusing lens 113 and optical inlet 112 which allows continuous steering of the laser beam 116 over the surface 118a of the solid compound 118 during the deposition process. For co-deposition, at least two of the plurality of laser sources 114a, 114b or 114c are used. A sample of a solid compound 118 disposed in a suitable vessel 119 within the chamber 110 is positioned under 30-60 degrees with respect to substrate 120 for fabricating an OLED device 10, which substrate 120 is also disposed within the vacuum chamber 110.

Although only one vacuum chamber is illustrated, it should be understood that additional vacuum chambers may be employed in the method and system of the invention. Likewise, although only one vessel 119 is illustrated, it is to be understood that the method and system of the invention may also include additional vessels for retaining a sample, whether solid or in another form, particularly where methods of deposition such as thermal-resistive or electron beam evaporation are employed in the invention. Advantageously, the method and system of the present invention uses less material than other known deposition schemes. Since the cost of the material is relatively high, the method and system according to the present invention reduces manufacturing costs. It is to be understood that depending on the OLED application or the OLED dimensions, a suitable vacuum chamber or vacuum chambers can be made with different dimensions and shapes, and with different materials such as stainless steel or borosilicate glass, provided they comprise all the aforementioned components of the system and maintain a suitable vacuum.

Referring to FIG. 2, a laser source 114a in a preferred embodiment is an air cooled pulsed alexandrite laser which generates double beam tunable laser radiation. The laser has pulse repetition rate of up to 30 Hz and provides for up to 500 mJ/pulse Q-switched or 3 J/pulse free lasing at 760 nm. The UV version provides up to 150 mJ/pulse Q-switched and 20 mJ/pulse free lasing at 380 nm. This laser can be tuned from 720-760 nm at the fundamental wavelength and from 360-430 nm at the second harmonic. A suitable double beam tunable alexandrite laser for use in the present invention is available from Laser Energetics, Inc., of Mercerville, N.J. A second laser source 114b is a pulsed tunable YAG laser model CFR200 available from Big SkyLaser Technologies, Inc., Bozeman, Mont., with a fundamental wavelength of 1064 nm, and 532 nm at the second harmonic operating at a pulse repetition rate of up to 60 Hz. This laser may generate up to 250 mJ energy/pulse. Laser source 114c in this embodiment is a pulsed XeCl excimer laser PLX200 operating at 308 nm, which laser is available from Lambda Physik-of Gottingen, Germany.

It is to be understood that the components required in providing a suitable vacuum chamber, such as vacuum valves, vacuum gauges, gas inlets/outlets adjacent to a vacuum chamber, vacuum pumps, pressure controllers, substrate holders, and other components have not been illustrated, as these components for providing and maintaining a vacuum are known to those with ordinary skill in the art.

It is to be understood also that the components required in providing a suitable power and control for laser sources, such as computers, controllers, optical component holders, optical mirrors, optical reflectors, focusing lenses, frames and cases, gas sources and other components have not been illustrated, as these components for providing and maintaining laser radiation and its delivery are known to those with ordinary skill in the art.

The method and system of the invention is particularly suited for compounds having a high melting point from about 300 to 1000° C., while lower melting point compounds may also be readily deposited without thermally degrading, either chemically or physically. According to the method and system described herein, the compounds employed in the invention are capable of being deposited in a vacuum having a background pressure less than one atmosphere, preferably about 10⁻⁵ to about 10⁻⁹ torr. The method and system of the invention for fabricating an OLED have the advantage that the organic compounds and coordination complexes employed may be laser deposited, which compounds cannot be deposited using other techniques without deleteriously altering the structure of the compound. Altering the structure of the compounds by using techniques other than laser deposition can be deleterious to the completed OLED. By employing laser deposition in fabricating OLEDs, less material is consumed than in the aforementioned processes.

Referring to FIG. 2a, a laser beam 116 is directed upon the top surface 118a of the solid sample 118 to volatize the sample 118. Referring to FIG. 2b, the volatized sample 118a is deposited upon the receiving substrate 120 and thereby forms a layer 140 of the OLED device 10. Referring to FIG. 2c, an additional organic layer or layers 150 illustrated as being deposited upon layer 140 may also be formed by laser deposition according to the method of the invention. The additional layer(s) 150 may be formed by laser deposition according to the method of the invention, and by alternative techniques, including but not limited to thermal-resistive evaporation, metallo-organic chemical vaporization, electron beam evaporation, and RF/DC sputtering, without removing the OLED device during production from the vacuum system. For example, more than one layer of the layers 150 may be formed by co-deposition of host and dopant compound either by pulsed laser deposition employing two or three laser sources, or one layer by pulsed laser deposition and another layer by any alternative technique, all of which are deposited within the same vacuum system. Since humidity has been found to cause failure of OLED devices, one of the advantages of the method and system of the present invention is that multiple methods of deposition of the different layers of the OLED may be used without removing the device from the vacuum system to produce a superior product. The present method and system of the invention also allows for large-scale commercial production of OLEDs since the fabrication of the OLED is in a controlled environment.

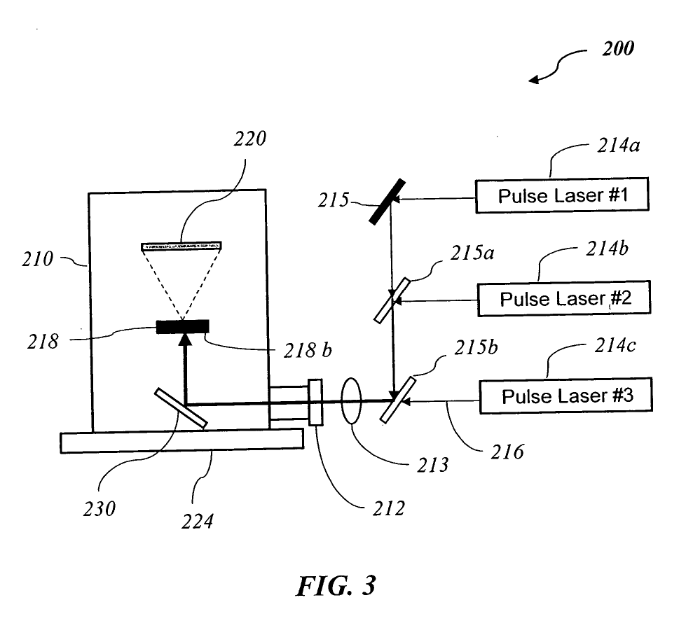

Referring to FIG. 3, a laser deposition system 200 according to an alternative preferred embodiment of the invention is illustrated. The laser deposition system 200 includes all the components described above with regard to FIG. 2, with the exception that the laser beam 216 is directed upon the bottom surface 218b of the sample 218 with a reflecting mirror 230 which redirects the laser beam inside the chamber to the bottom surface 218b. The mirror 230 can also be placed outside the vacuum chamber provided that the optical inlet is disposed adjacent the bottom plate 224 of the chamber. As illustrated in FIG. 3, the solid sample 218 is positioned to be substantially parallel to the substrate 220.

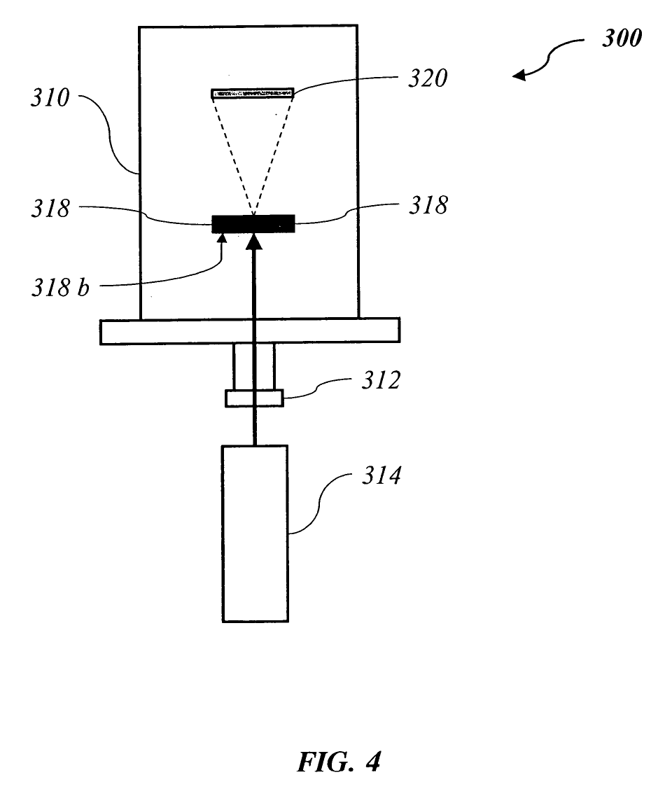

Referring to FIG. 4, a laser deposition system 300 according to an alternative preferred embodiment of the invention is illustrated. The laser deposition system 300 includes all the components described above with regard to FIG. 2, with the exception that the optical inlet 312 is disposed under the bottom plate 324 of the vacuum chamber. According to this aspect of the invention, the laser beam 314 is directed upon the bottom surface 318b of the sample. This configuration allows for the reduction of the overall dimensions of a laser deposition system.

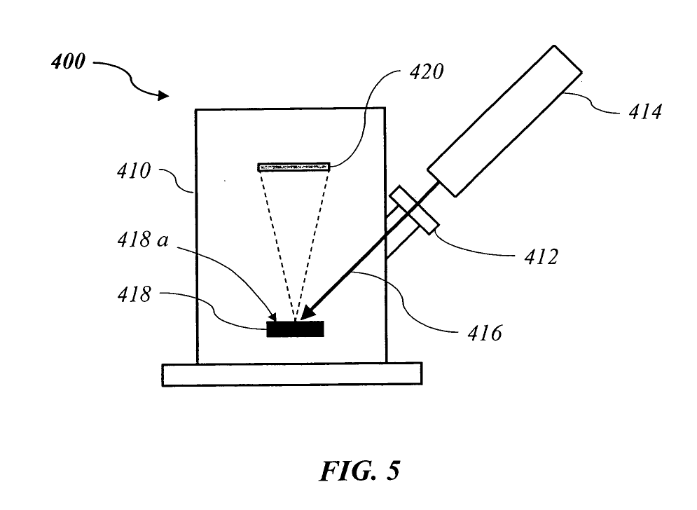

Referring to FIG. 5, a laser deposition system 400 according to yet another preferred embodiment of the invention is illustrated. The laser deposition system 400 includes all the components described above with regard to FIG. 2, with the exception that the optical inlet 412 is attached to the vacuum chamber 410 at an angle chosen from a range of 30 to 60 degrees with respect to the sample compound 418 so that the laser beam 416 is directed upon the top surface 418a of the sample compound 418 at the same angle. As in FIG. 2, a sample of a solid compound 418 is positioned to be substantially parallel to substrate 420. In this configuration the surface 418a of a solid compound 418 is parallel to the surface of a substrate. This configuration can be implemented for the deposition of organic compound and coordination complexes over substrates having large dimensions, where the solid compound 418 can be moved within the plane parallel to the plane of the substrate. Examples of substrates having large dimensions include computer monitors and flat TV screens.

The device 10 of the present invention is suitable for operation in both active or passive matrix arrays. In a passive matrix array, the current drive circuitry is external to the array, and in an active matrix array, the current drive circuitry includes one or more transistors that are formed within each color picture element (pixel). Each OLED device 10 typically serves as one color component of a pixel. The OLED device 10 according to the present invention may be included, for example, as a plurality of pixels in a light emitting display device, or as part of a single pixel device. Arrays of OLED devices may be used to create two-dimensional flat panel displays, or monochrome or color displays.

In OLED devices 10, pixels typically have dimensions of 80×300 microns, and are deposited using a fine metal shadow mask in a vacuum chamber. The specific color displayed is a blend of three components of the color spectrum, namely, red, green and blue. Pixels can be implemented for use in a display screen by arranging red, green, and blue OLED devices together to build an image.

Passive matrix arrays are formed by patterning the lower electrode, for example, the ITO layer on glass, into stripes. A shadow mask structure is then formed perpendicular to the electrode stripes using photolithography. Thereafter, the remainder of the stack and the upper electrode may be deposited over the array, to ensure that the upper electrode will not be continuous, but will consist of stripes similar to those of the lower electrode. In this manner, a row and column display is provided without subjecting the organic layers of the OLED to photolithographic processing.

In an active matrix, the row and column structures are built into the substrate using standard semiconductor techniques. The completed substrate thus has an array of discrete electrode, each one corresponding to a point in the matrix. The organic stack can then be deposited, followed by a transparent electrode, over the array, without the need for further patterning. In this type of array, the OLED is upwardly emitting, i.e., the upper cathode electrode must be transparent, whereas OLEDs generally include a transparent lower anode electrode. The low cost and ease of making the OLEDs according to the invention make compact, high resolution displays practical.

Depending upon the selected matrix array, the OLEDs may be formed on transparent substrates for passive displays, or semiconductor substrates for active displays. The organic light emitting devices operate under alternating current (AC) and or direct current DC). Suitable arrangements for driving the OLED in either type of array are known to those with ordinary skill in the art, and hence are not herein described.

Preferred voltages are, for example, from about 2-10 volts, and preferred driving currents are, for example, from about 1 to about 1000 mA/cm², and more preferably, from about 10 mA/cm² to about 200 mA/cm², regardless of the chosen array. Driving voltages and currents outside the above ranges may also be used. Both types of arrays have advantages and disadvantages in terms of cost and power consumption, in addition to other considerations.

Preferred stack structures for the OLED devices 10 according to the invention include, but are not limited to the following: ITO(1500 Å)/TPD(750 Å)/CBP+1% Eu(2-HQC)₃(350 Å)/BCP(80 Å)/Alq₃(400 Å)/LiF(10 Å)/Al(1500 Å); ITO(1500 Å)/TPD(750 Å)/CBP+Eu(DPA)₃(NH₂Me₂)₃(400 Å)/CBP(100 Å)/Alq₃(350 Å)/LiF(10 Å)/Al(1500 Å); ITO(1500 Å)/TPD(400 Å)/CBP+2% Eu(TTA)₃(TPPO)₂(400 Å)/BCP(80 Å)/Alq₃(350 Å)/LiF (10 Å)/Al(1000 Å) and ITO(1500 Å)/TPD(750 Å)/CBP+1.2% Eu(TTA)₃(TPPO)₂(400 Å)/BCP(100 Å)/Alq₃(350 Å)/LiF(10 Å)/Al(612 Å)/Ag(620 Å), which all emit a red light. Another preferred stack structure for the OLED device 10 includes ITO(1500 Å)/NPD(700 Å)/CBP+1% NaSSAA(350 Å)/BCP(100 Å)/Alq₃(350 Å)/LiF(10 Å)/Al(1000 Å), which provides a blue light. Another preferred stack structure for the OLED device 10 includes ITO(1500 Å)/CuPc(100 Å)/TPD(700 Å)/CBP+2%2-HPClQ(400 Å)/BCP(100 Å)/Alq₃(350 Å)/LiF(10 Å)/Al(1500 Å), which provides a green light.

The following examples are for illustrative purposes only, and are not intended to limit the scope of the invention, which is defined solely by the appended claims.

### EXAMPLES

In each of the following examples, laser deposition of an organic or coordination complex substance is achieved by using a vacuum chamber with an optical window for receiving a laser beam. The chamber also includes several thermal-resistive boats used in conventional thermal deposition. A laser source is disposed adjacent to the vacuum chamber. A solid sample of an organic compound, coordination complex, or a combination of organic compounds and coordination complexes is placed into the vacuum chamber a selected distance from a substrate onto which the OLED will be fabricated. The solid sample may take the form of a pellet, film, or slab. The temperature of the sample may be varied from ambient temperature to the temperature of liquid nitrogen (77K). The pressure in the chamber is reduced to about 5×10⁻⁶ torr or below, and maintained at about the same level during the process. A pulsed laser beam(s) of coherent light directed onto the sample vaporizes the compound(s), resulting in the deposition of the compound or compounds as an OLED layer. The thickness of the layer may vary between about 100-2000 Angstroms, depending upon the OLED stack structure and application. Other layers that are selected to constitute the OLED may be deposited by conventional thermal deposition, and other techniques, such as metallo-organic chemical vaporization, electron beam evaporation, and RF/DC sputtering, using the same vacuum chamber.

### Example 1

A pellet made of an organic chelate, 2,6-Pyridine dicarboxylic acid europium dimethylamine complex 3:1:3 (Eu(DPA)₃(NH₂Me₂)₃), was placed into a vacuum chamber as illustrated in FIG. 2. In this example, only a double beam alexandrite laser 114a referred to as Pulse Laser #1 was used. A laser beam 116 having a single-mode wavelength of 760 nm was redirected using mirror 115 and semitransparent mirrors 115a and 115b upon the surface of a pellet 118 forming a spot of about 1 mm in diameter to deliver energy of 80 mJ at a pulse repetition rate of 10 Hz. Deposition for 25 minutes onto a glass substrate resulted in a substantially uniform film having a thickness of 1400 Å.

### Example 2

Similarly to Example 1, a pellet was made of an organic chelate, Eu(DPA)₃(NH₂Me₂)₃, and placed into a vacuum chamber as illustrated in FIG. 2a. Again, only a double beam alexandrite laser 114a referred to as Pulse Laser #1 was used. A laser beam 116 having a wavelength of 760 nm was redirected using mirror 115 and semitransparent mirrors 115a and 115b and through focusing lens 113 upon the surface of a pellet 118 forming a spot of about 1 mm in diameter to deliver energy of 120 mJ at a pulse repetition rate of 10 Hz. Deposition for 25 minutes onto a glass substrate resulted in a substantially uniform film having a thickness of 1800 Å.

### Example 3

Similarly to Example 2, a pellet was made of an organic chelate, Eu(DPA)₃(NH₂Me₂)₃, and placed into a vacuum chamber as illustrated in FIG. 2. Two lasers 114a and 114c referred to as Pulse Lasers #1 and and #3 were simultaneously turned on. A laser beam having combined radiation wavelengths of 380 nm and 760 nm from a double beam alexandrite laser 114a operating at a pulse repetition rate of 10 Hz was redirected using mirror 115 and semitransparent mirrors 115a and 115b upon the surface of a pellet forming a spot of about 1 mm in diameter to deliver energy of 20 mJ at 380 nm and 120 mJ at 760 nm. A second laser beam having a frequency of 308 nm from the XeCl excimer laser 114c delivered energy of 100 mJ at a pulse repetition rate of 10 Hz through semitransparent mirror 115b. All laser beams were mixed and focused by focusing lens 113. Deposition for 20 minutes onto a glass substrate resulted in a substantially uniform film having a thickness of 1100 Å.

### Example 4

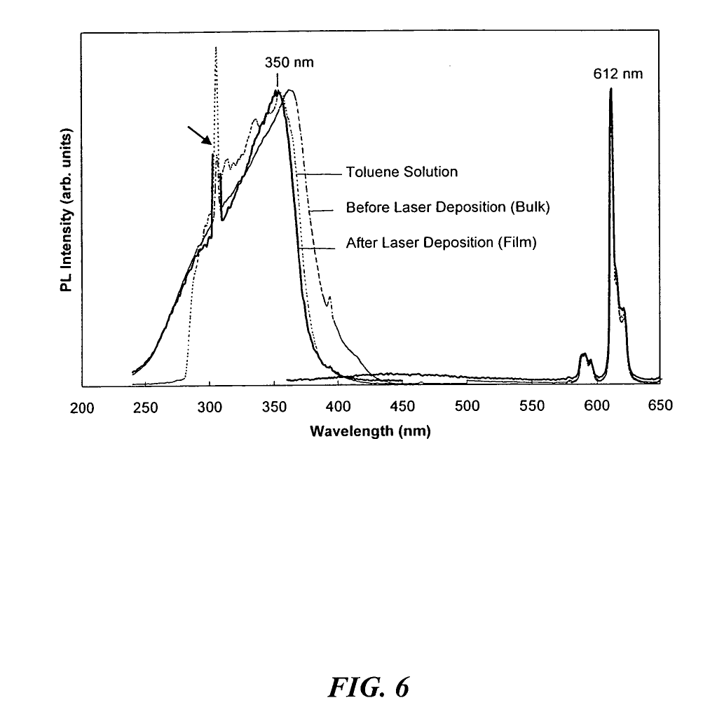

A pellet made of an organic chelate, Europium, tris(2-hydroxy-4-quinolinecarbonxylato) (Eu(2-HQC)₃), was placed into a vacuum chamber as illustrated in FIG. 2. In this example, a laser beam having combined radiation wavelengths 380 nm and 760 nm from a double beam alexandrite laser 114a operating at a pulse repetition rate of 10 Hz was redirected using mirror 115 and semitransparent mirrors 115a and 115b upon the surface of a pellet forming a spot of about 1 mm in diameter to deliver energy of 10 mJ at 380 nm and 100 mJ at 760 nm. Deposition for 7 minutes onto a glass substrate resulted in a substantially uniform film having a thickness of 1300 Å. Excitation and emission spectra obtained from this film are presented in FIG. 6 along with those from the same organic chelate in bulk form and in solution prior to laser deposition. Great similarities in the spectra demonstrate that laser evaporation does not change the molecular structure which, if changed, would otherwise be indicated by transformed excitation and emission spectra.

FIG. 6 illustrates the excitation and photoluminescence (PL) spectrum of Eu(2-HQC)₃ laser-deposited film (solid line) compared to PL and excitation spectra of the same material prior to laser deposition in bulk form (dashed line) and dissolved in toluene (dashed-dot line) and deposited according to the procedure described in Example 4. To depict them on the same plot, each spectrum was normalized to the corresponding peak intensity, and the vertical scale was given in arbitrary units. A sharp intensive peak at 306 nm marked with the bold arrow is a feature not related to the material property—it was a second harmonic of a fluorimeter's excitation laser centered at 612 nm, and was excluded from consideration. Excitation and PL spectra of the same material prior to laser deposition are also shown for comparison in FIG. 6, where the dashed line indicates the bulk compound and the dashed-dot line corresponds to the compound dissolved in toluene. A good match between the three spectra suggests that the complex's structure with the central europium ion and three organic ligands remain intact in the laser-deposited film. Eu(2-HQC)₃ has a melting temperature of 405° C., and attempts to form a similar film on a glass substrate by conventional thermal vacuum evaporation were unsuccessful.

### Example 5

Similarly to Example 4, a pellet was made of an organic chelate, Eu(2-HQC)₃, and placed into the vacuum chamber of the system as illustrated in FIG. 2. In this example, two lasers 114a and 114c referred to as Pulse Lasers #1 and #3 were simultaneously turned on. A laser beam having combined radiation at wavelengths of 380 nm and 760 nm from a double beam alexandrite laser 114a operating at a pulse repetition rate of 10 Hz was redirected using mirror 115 and semitransparent mirrors 115a and 115b upon the surface of a pellet forming a spot of about 1 mm in diameter to deliver energy of 10 mJ at 380 nm and 60 mJ at 760 nm. A second laser beam having a frequency of 308 nm from the XeCl excimer laser 114c delivered energy of 100 mJ at pulse repetition rate 10 Hz through semitransparent mirror 115b. A second laser beam having a wavelength of 308 nm from the XeCl excimer laser 114c delivered energy of 100 mJ at a pulse repetition rate of 10 Hz through semitransparent mirror 115b. All laser beams were mixed and focused by focusing lens 113. Deposition for 20 minutes onto a glass substrate resulted in a substantially uniform film having a thickness of 1200 Å. In a subsequent run, the energy of the alexandrite laser 114a was increased from 60 mJ to 100 mJ at 760 nm, which resulted in an increased thickness of 2690 Å for the deposited film. In a subsequent run, the energy of the excimer laser 114c was decreased from 100 mJ to 50 mJ, while the energy levels from the alexandrite lasers 114a were tuned to 10 mJ at 380 nm and 100 mJ at 760 nm, respectively. Deposition for 10 minutes produced a substantially uniform film of 400 Å.

### Example 6

In this example, an organic chelate, Eu(DPA)₃(NH₂Me₂)₃, was doped by means of laser deposition into host material, 4,4‘-N-N’-dicarbazole biphenyl (CBP), which was co-deposited by thermal resistive evaporation from an adjacent boat in the same vacuum chamber. Similarly to Example 1, a pellet was made of an organic chelate Eu(DPA)₃(NH₂Me₂)₃, and placed into the vacuum chamber as illustrated in FIG. 2. Two lasers 114a and 114c referred to as Pulse Lasers #1 and #3 were simultaneously turned on. A laser beam having combined radiation at wavelengths 380 nm and 760 nm from a double beam alexandrite laser 114a operating at a pulse repetition rate of 10 Hz was redirected using mirror 115 and semitransparent mirrors 115a and 115b upon the surface of a pellet forming a spot of about 1 mm in diameter to deliver energy of 10 mJ at 380 nm and 60 mJ at 760 nm. A second laser beam having a wavelength of 308 nm from the XeCl excimer laser 114c delivered energy of 100 mJ at a pulse repetition rate of 10 Hz through semitransparent mirror 115b. All laser beams were mixed and focused by focusing lens 113. Deposition for 8 minutes onto a glass substrate resulted in a substantially uniform film having a thickness of 370 Å. In a subsequent run, the energy of the dual beam alexandrite laser 114a operating at a pulse repetition rate of 10 Hz was increased from 10 mJ to 20 mJ at 380 nm, and from 60 mJ to 120 mJ at 760 nm. The thickness of the deposited film also increased to 450 Å. In a subsequent run, the energy of the alexandrite laser 114a was further increased from 10 mJ to 100 mJ at 380 nm, and from 120 mJ to 160 mJ at 760 nm. Deposition for 7 minutes produced a film of 830 Å thickness.

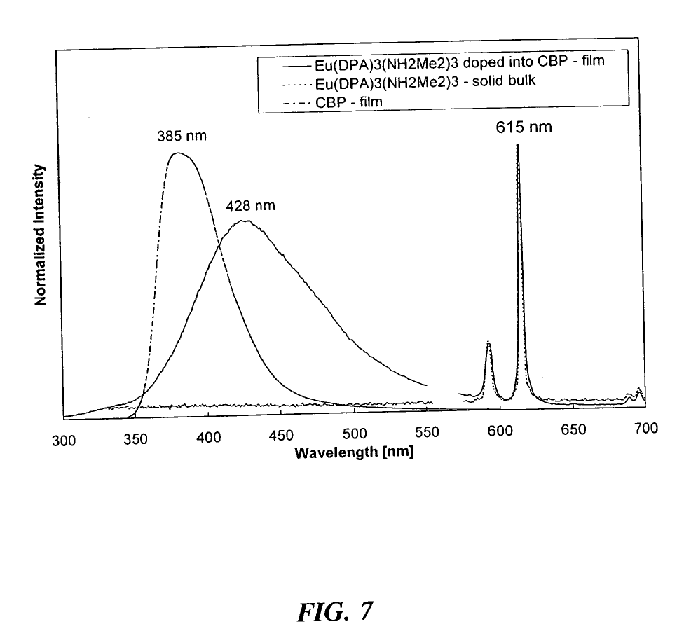

Emission spectrum of the film of Eu(DPA)₃(NH₂Me₂)₃ doped into CBP by laser deposition technique according to an aspect of the invention is depicted in FIG. 7 by a solid line. A good match in the position of the sharp peak at 615 nm (⁵Dₓ-⁷Fₓ transitions in Eu³⁺ ion) between the solid bulk Eu(DPA)₃(NH₂Me₂)₃ prior to laser deposition (dashed line) and the laser-deposited film indicates that the complex remains intact after laser deposition is complete, and that the intramolecular energy transfer from the ligands to the central Eu³⁺ ion takes place. However, the spectrum of the laser-deposited film has a new broad peak centered at 428 nm, which is not present in the spectrum of the initial compound. This peak cannot be attributed to CBP, the emission spectrum of which is depicted by the dashed-dot line in FIG. 7 and which exhibits a peak at 385 nm. The new peak at 428 nm may result from the formation of excimers between CBP and ligands of 2,6-Pyridine dicarboxylic acid europium dimethylamine complex. Adachi, et al., J.Appl. Phys. 87(11), p.8050 (2000) have reported a similar band appearing at high current densities in the electroluminescent spectrum of an OLED with 2% Eu(TTA)₃Phen complex doped into CBP as an emitting layer. While laser deposition of this material with a melting temperature of greater than 300° C. produced a film, it proved impossible to form any film of this organic chelate on a glass substrate by conventional resistive thermal evaporation.

FIG. 7 illustrates the emission spectrum of the film of Eu(DPA)₃(NH₂Me₂)₃ doped into CBP by a laser deposition technique (solid line) according to an aspect of the invention. This spectrum, obtained by photo excitation at 280 nm, is compared to the emission spectra of solid bulk 2,6-Pyridine dicarboxylic acid europium dimethylamine complex 3:1:3 (dashed line) prior to laser deposition, and also to a CBP film (dashed-dot line) formed on a glass substrate by conventional thermal vapor deposition techniques. To depict them on same plot, each spectrum was normalized to the corresponding peak intensity. Vertical scale was given in arbitrary units. The discontinuity in the spectra of both a solid bulk Eu(DPA)₃(NH₂Me₂)₃ and film of same material doped in CBP extending from 550 nm to 570 nm contains a sharp peak centered at 560 nm, which rises from a second harmonic of a fluorimeter's excitation at 280 nm. Since this feature does not relate to the material property it can be excluded from further consideration, and to avoid any confusion the peak has been eliminated from the spectra.

### Example 7

A glass substrate with indium-tin-oxide (ITO) film having a thickness of 1500 Å is placed into a rotational substrate holder inside a vacuum deposition chamber with ITO facing deposition boats filled with materials to be deposited. A 700 Å thick film of α-NPB is deposited through a first shadow mask having a square window overlapping OLED pixel areas upon an ITO anode layer at a rate of 2 Å/s to form a hole transport layer (HTL). Thereafter, a 350 Å thick emitting layer (EML) is deposited via co-deposition of a dopant Eu(2-HQC)₃ by means of a pulse laser and a host compound, carbazole biphenyl (CBP) by means of thermal vapor deposition, through the same shadow mask. The deposition rate is maintained at about 0.6 Å/s for the dopant and 2 Å/s for the host during the course of deposition to achieve a 4% doping level. This provides a weight ratio of 4:96 for dopant and host, respectively. Next, a 80 Å thick film of bathocuproine (BCP) is deposited as a hole blocking layer (HBL), again through the same shadow mask. A 400 Å thick electron transport layer (ETL) of Alq₃ is deposited onto the hole blocking layer, through same shadow mask. Thereafter, the first shadow mask having a square window is replaced with a second shadow mask having several smaller windows comprising OLED pixels. A 10 Å film of LiF is thereafter deposited onto the electron transport layer as an HIL through the second shadow mask. A 1500 Å thick layer of aluminum is subsequently deposited as a cathode layer onto the HIL through the second shadow mask.

The OLED thus fabricated having the following stack structure: ITO(1500 Å)/α-NPB(700 Å)/CBP+4% Eu(2-HQC)₃(350 Å)/BCP(80 Å)/Alq3(400 Å)/LiF(10 Å)/Al(1500 Å) is transferred into inert-atmosphere dry box, where it is encapsulated for further characterization with a blank piece of glass coupled to the substrate by an adhesive means.

### Example 8

In this example, a glass substrate with indium-tin-oxide (ITO) film having a thickness of 1500 Å is placed into a rotational substrate holder inside a vacuum deposition chamber with the ITO layer facing a plurality of deposition boats containing materials to be deposited as hereafter described. A 400 Åfilm of TPD is deposited through a first shadow mask having a square window overlapping the OLED pixel areas onto the ITO anode layer at a rate of 1-2 Å/s to form a hole transport layer (HTL). Thereafter, a 400 Å emitting layer (EML) is deposited via co-deposition of a dopant 2,2′-(1,4-phenylene)bis-4H-3,1-benzoxazinon-4-one by means of a pulse laser, and a host compound, carbazole biphenyl (CBP) by means of thermal vapor deposition, through the same shadow mask. The deposition rate is maintained at about 0.6 Å/s for the dopant and at about 2 Å's for the host during the course of deposition to achieve a 4% doping level. This provides a weight ratio of 4:96 for dopant and host, respectively. A 400 Å electron transport layer (ETL) of Alq₃ is deposited onto the EML through the same shadow mask. Thereafter, the first shadow mask having a square window is replaced with a second shadow mask having several smaller windows comprising OLED pixels. A 10 Å film of LiF is thereafter deposited onto the electron transport layer as an HIL through the second shadow mask. A 1000 Å layer of aluminum is subsequently deposited as a cathode layer onto the HIL through the second shadow mask.

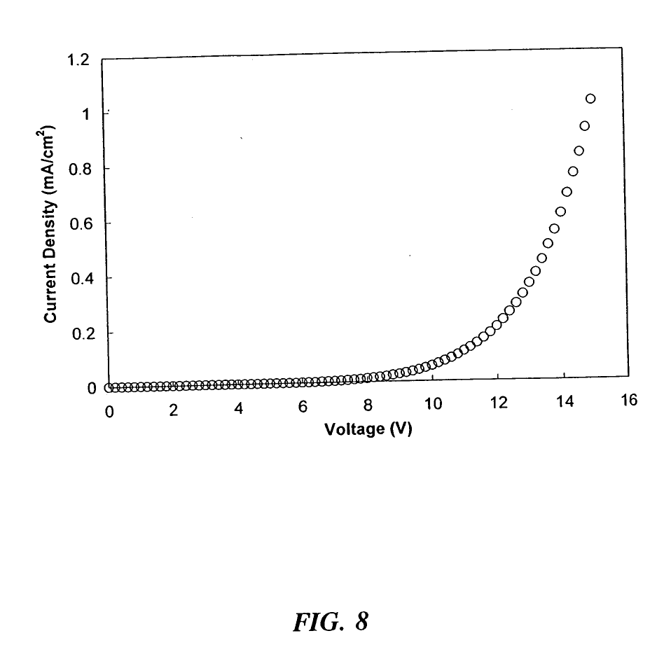

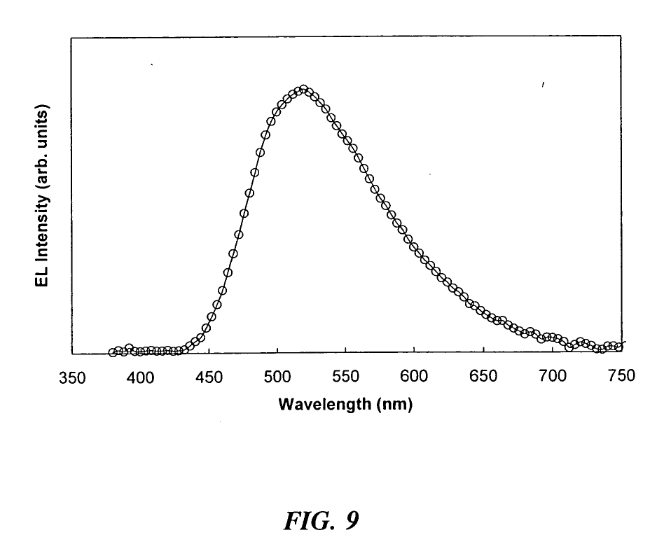

The OLED thus fabricated having the following stack structure: ITO(1500 Å)/TPD(400 Å)/CBP+4% 1,4PPO(400 Å)/Alq3(400 Å)/LiF(10 Å)/Al(1000 Å) is transferred into inert-atmosphere dry box, where it is encapsulated for further characterization with a blank piece of glass coupled to the substrate by an adhesive means. The current density versus voltage is illustrated in FIG. 8, while the electroluminescent spectrum obtained at current density of 1 mA/cm² is illustrated in FIG. 9.

Referring to FIG. 8, the current density is plotted against voltage for an OLED fabricated according to the invention having a stack design ITO(1500 Å)/TPD(400 Å)/CBP+4% 1,4PPO(400 Å)/Alq3(400 Å)/LiF(10 Å)/Al(1000 Å), where the dopant 2,2′-(1,4-phenylene)bis-4H-3,]-benzoxazinon-4-one is co-deposited by means of two wavelengths (pulsed laser radiation), while the host CBP is co-deposited by means of thermal vacuum evaporation.

Referring to FIG. 9, an electroluminescence spectrum of an OLED having the stack structure according to FIG. 8 is illustrated.

### Example 9

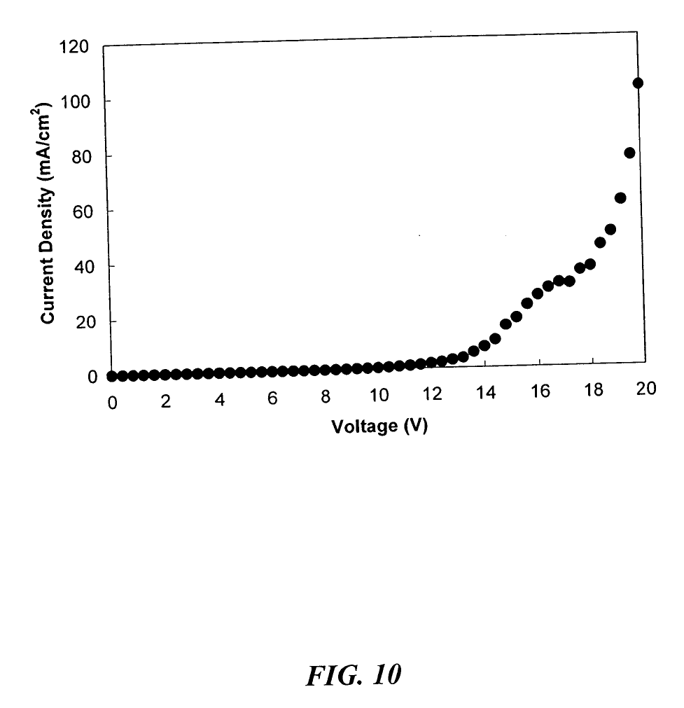

In this example, a glass substrate with indium-tin-oxide (ITO) film having a thickness of 1500 Å is placed into a rotational substrate holder inside a vacuum deposition chamber with the ITO layer facing a plurality of deposition boats filled with materials to be deposited as hereafter described. A 750 Å thick film of TPD is deposited through a first shadow mask having a square window overlapping OLED pixel areas upon an ITO anode layer at a rate of 2 Å/s to form a hole transport layer (HTL). Thereafter, a 400 Å thick emitting layer (EML) is deposited via co-deposition of a dopant Tris(4,4,4-trifluor-2-thenoyl-(1,3-butandionato-O,O′)Europium-di-(Triphenylphosphinoxide) (Eu(TTA)₃(TPPO)₂) by means of a pulse laser, and a host compound, carbazole biphenyl (CBP), by means of thermal vapor deposition, through the same shadow mask. The deposition rate is maintained at about 0.4 Å/s for the dopant and 2 Å/s for the host during the course of deposition to achieve a 1.2% doping level. Next, a 100 Å thick film of bathocuproine (BCP) is deposited as a hole blocking layer (HBL), through the above shadow mask. A 350 Å thick electron transport layer (ETL) of Alq₃ is deposited onto the hole blocking layer, using the above shadow mask. Thereafter, the first shadow mask having a square window is replaced with a second shadow mask having several smaller windows comprising OLED pixels. A 10 Å film of LiF is thereafter deposited onto the electron transport layer as a hole injection layer (HIL) through the second shadow mask. A 612 Å thick layer of aluminum is subsequently deposited as a cathode layer onto the HIL through the second shadow mask followed by a 620 Å thick layer of silver. The OLED thus fabricated having the following stack structure: ITO(1500 Å)/TPD(750 Å)/CBP+1.2% Eu(TTA)₃(TPPO)₂(400 Å)/BCP(100 Å)/Alq3(350 Å)/LiF(10 Å)/Al(612 Å)/Ag(620 Å) is transferred into inert-atmosphere dry box, where it is encapsulated for further characterization with a blank piece of glass coupled to the substrate by an adhesive means. Electrical and optical characteristics of the OLED of this Example are shown in FIGS. 10-13. Referring to FIG. 10, the current density is plotted against voltage for an OLED fabricated according to the invention having a stack design ITO(1500 Å)/TPD(750 Å)/CBP+1.2% Eu(TTA)₃(TPPO)₂(400 Å)/BCP(100 Å)/Alq3(350 Å)/LiF(10 Å)/Al(612 Å)/Ag(620 Å).

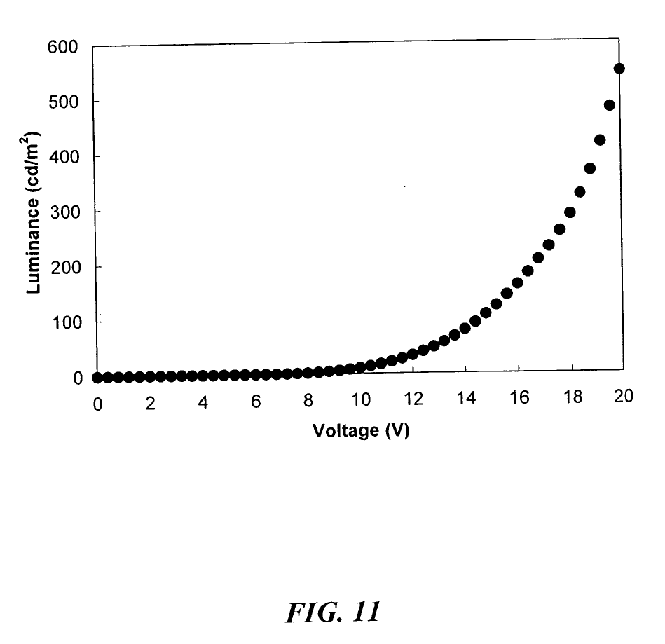

Referring to FIG. 11, the luminance is plotted against voltage for an OLED having the stack structure according to FIG. 10.

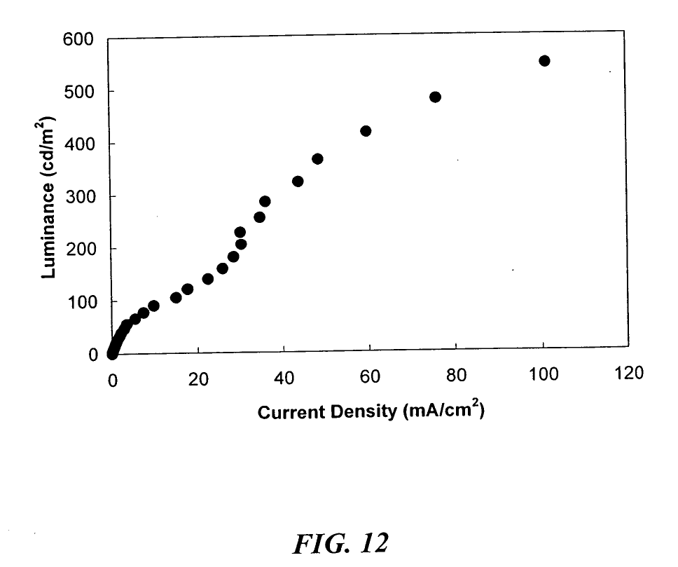

Referring to FIG. 12, the luminance is plotted against current density for an OLED having the stack structure according to FIG. 10.

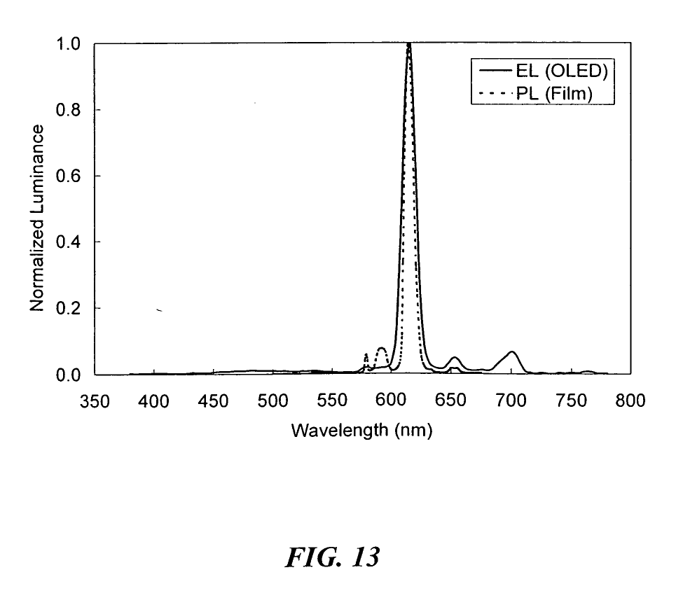

Referring to FIG. 13, both an electroluminescence spectrum (depicted by a solid line) of an OLED having the stack structure according to FIG. 10 and a photoluminescence spectrum of Eu(TTA)₃(TPPO)₂ film (depicted by dashed line) are illustrated. Both spectra are identical in most detail. A good match in the position of the sharp peak at 615 nm (⁵Dₓ-⁷Fₓ transitions in Eu³⁺ ion) in spectra of Eu(TTA)₃(TPPO)₂ film (dashed line) and the OLED (solid line) indicates that the complex remains intact after the laser deposition is complete, and that in the OLED emitter layer, the intermolecular energy transfer takes place from CBP host to Eu(TTA)₃(TPPO)₂ dopant, as well as the intramolecular energy transfer from the ligands of the dopant molecule to its central Eu³⁺ ion.

Although the invention has been described with regard to the preferred embodiments, the details of the description are not to be construed as a limitation thereof. Various embodiments, changes, modifications, and equivalent substitutions may be made without departing from the spirit and scope thereof, which is defined solely by the appended claims.

What is claimed is:

1. A method for fabricating an organic light emitting device (OLED), comprising the steps of:
providing a vacuum chamber, said vacuum chamber including an optical inlet for receiving a plurality of coherent light wavelengths;
providing at least one pulsed laser source adapted to generate a plurality of coherent light wavelengths between about 150 nm and about 1100 nm;
providing at least one retainer in said vacuum chamber for retaining an organic or coordination complex solid sample;
disposing an organic compound or coordination complex solid sample in said at least one retainer;
providing a receiving substrate in said vacuum chamber for building an OLED upon;
emitting from said at least one laser source at least two pulsed coherent light wavelengths tuned at different frequencies from said at least one pulsed laser source through said optical inlet to strike said solid sample and thereby form a volatized sample therefrom; and
depositing said volatized sample on said receiving substrate to thereby form a layer of said OLED.

2. The method according to claim 1, wherein the solid sample has a melting point from 300 up to 1000° C.

3. The method according to claim 1, wherein the solid sample is an organic compound having a melting point of less than 300° C.

4. The method according to claim 1, wherein the solid sample is a coordination complex having a melting point of less than 300° C.

5. The method according to claim 1, further including the step of: providing the solid sample at a temperature between ambient temperature and about 77K.

6. The method according to claim 1, wherein the thickness of said layer ranges between about 100 to 2000 Angstroms.

7. The method according to claim 1, wherein said solid sample is in the form of a pellet, slab or film.

8. The method according to claim 1, further including the step of: depositing an additional layer onto said layer formed by pulsed laser deposition using thermal-resistive evaporation, metalo-organic chemical vaporization, electron beam evaporation, and RF/DC sputtering.

9. The method according to claim 1, further including the step of forming a hole injection layer.

10. The method according to claim 1, further including the step of forming a hole transport layer.

11. The method according to claim 1, further including the step of forming an emissive layer.

12. The method according to claim 1, further including the step of forming a hole blocking layer.

13. The method according to claim 1, further including the step of forming an electron transport layer.

14. The method according to claim 1, further including the step of forming an electron injection layer.

15. The method according to claim 1, further including the step of codepositing a host compound and at least one emitter compound with two laser sources.

16. The method according to claim 1, wherein said laser beam of said plurality of coherent light wavelengths strike the solid sample simultaneously.

17. The method according to claim 1, wherein said plurality of coherent light wavelengths are operated at a different pulse repetition rate and said laser beam of said plurality of coherent light wavelengths strikes the solid sample at different times.

18. The method according to claim 1, wherein said coordination complex compounds are selected from the group consisting of:
tris(4,4,4-trifluor-2-thenoyl-(1,3-butandionato-O,O′)Europium-di-(Triphenylphosphinoxide); Europate(1),tetrakis(4,4,4,-trifluoro-1-(phenyl)-1,3-butandionato-O,O′)-,hydrogen complex with N-methylmethanamine (Eu(BTA)4(NH2Me2); Europate (1-),tetrakis(4,4,4,-trifluoro-1-(2-thienyl)-1,3-butandionato-O,O′)-,ammonium; 5-[[4-dimethylamino)phenyl]methylene-2,4,6-(1H, 3H, 5H)-pyrimidinetrione; 2,6-Pyridine dicarboxylic acid europium dimethylamine complex 3:1:3; and Europium, tris(2-hydroxy-4-quinolinecarbonxylato).

19. The method according to claim 1, wherein said organic compounds are selected from the group consisting of:
2-Naphthalenesulfonamide, N-[2-(4-oxo-4H-3,1-benzoxazin-2-yl)phenyl]; Benzenesulfonamide 4-methyl-N-[2-(4-oxo-4H-3,1-benzoxazin-2-yl)phenyl]; 2-(2-Hydroxyphenyl)-benzthiazol; 2,5-Dihydroxyterephthalic acid diethyl ester; N-(5-sodium sulfosalicoyl) anthranilic acid; 4 (1H)-Quinazolinone, 2-(5-chloro-2-hydroxyphenyl); Benzoxazol 2,2′-(2,5-thiophendiyl)-bis[5-1,1′-dimethylethyl)]; 5-[[4-(dimethylamino)phenyljmethylene]-2,4,6(1H,3H,5H)-pyrimidinetrione; and aryl benzoxazinones and quinazolinones.

20. The method according to claim 1, wherein the pulsed laser source is a YAG, excimer, or alexandrite laser, or a combination thereof.

21. A deposition system for OLED fabrication, said system comprising:
a laser deposition apparatus comprising at least one pulsed laser source adapted to generate a plurality of coherent light wavelengths between about 150 nm and about 1100 nm for forming a layer of an OLED; and
a vacuum chamber comprising an optical inlet for receiving a plurality of coherent light wavelengths tuned at different frequencies from said pulsed laser source and at least one retainer for retaining a solid organic or coordination complex substance.

22. The system according to claim 21, wherein said laser source is YAG, excimer or alexandrite laser or combinations thereof.

23. The system according to claim 22, further comprising:
at least one additional laser deposition apparatus for forming said OLED layer comprising a pulsed laser source adapted to generate a coherent light wavelength of about 308.

24. The system according to claim 23, further comprising an alternative deposition apparatus for performing alternative techniques within said vacuum chamber, including thermal resistive evaporation, organic vapor phase deposition, electron beam evaporation, or RF/DC sputtering.

25. An organic multilayer electroluminescent device including an anode and a cathode, and comprising therebetween an emissive layer deposited by laser deposition according to the method of claim 1.

26. The method according to claim 19, wherein said aryl benzoxazinones and quinazolinalones are selected from the group consisting of: 2,2′-(1,4-phenylene)bis-4H-3,1-benzoxazin-4-one; 2,2′-(1,4-naphthylene)bis-4H-3,1-benzoxazin-4-one; [2,2′]bi-[benz[d][1,3]oxazinyl]-4,4′-dione; 2,2′,2″-(1,3,5-phenylene)tris-4H-3,1-benzoxazin-4-one; 2,2′-(2,5-pyridyl)bis-4H-3,1-benzoxazin-4-one; 2,2′-(1,3-phenylene)bis-4H-3, 1-benzoxazin-4-one; 2,2′-(1,4-naphthylene)bis-4H-3,1-benzoxazin-4-one; 2,2′-(1,4-phenylene)-2,3,5,6-tetrafluoro)bis-4H-3,1-benzoxazin-4-one; 3H,3′H-[2,2′]-1,4-phenylene-bis-quinazol in-4-one; 2,2′-(1,4-pyridyl)bis-4H-3,1-benzoxazin-4-one; 2,2′-(1,4-phenylene-2,5-diacetoxy)bis-4H-3,1-benzoxazin-4-one; 2,2′-(1,4-phenylene-2,5-dihydroxy)bis-4H-3,1-benzoxazin-4-one; 3H, 3′H-[2,2′]-biquinazolinyl-4,4′-dione; and 2,2″-(4,4″-biphenylene)bis-4H-3,1-benzoxazinone.

27. The system according to claim 21, wherein said two wavelengths strike the solid sample simultaneously.

28. The system according to claim 21, wherein said two wavelengths strike the solid sample at different times.

29. The system according to claim 23, wherein said pulsed laser source comprises an Alexandrite laser and an XeCl laser.

30. The method according to claim 1, further including the step of providing a second pulsed laser source adapted to generate a coherent light wavelength of about 308 nm.

31. The method according to claim 30, wherein said pulsed laser source comprises an Alexandrite laser and an XeCl laser.

32. The method according to claim 1, wherein said pulsed laser source is a gas laser.

33. The method according to claim 1 wherein said pulsed laser source is a solid state laser.

34. The method according to claim 1, wherein said pulsed laser source emits coherent light with a wavelength from about 250 nm to about 1050 nm.

35. The method according to claim 1, wherein said pulsed laser source emits coherent light with a wavelength of about 308 nm.

36. The method according to claim 1, wherein said pulsed laser source emits coherent light with a wavelength between about 490 nm and about 1040 nm.

37. The method according to claim 1, wherein said pulsed laser source emits coherent light with a wavelength between about 380 nm and about 760 nm.

38. The method according to claim 1, wherein said pulsed laser source emits coherent light with a wavelength of 760 nm.

39. The method according to claim 1, wherein said pulsed laser source emits two coherent light wavelengths of 380 nm and 760 nm.

40. The method according to claim 39, wherein a second pulsed laser source emits a coherent light beam with a wavelength of 308 nm and is combined with the coherent light beams with wavelengths of 380 nm and 760 nm.

41. The system according to claim 21, wherein said pulsed laser source is a gas laser.

42. The system according to claim 21 wherein said pulsed laser source is a solid state laser.

43. The system according to claim 21, wherein said pulsed laser source emits coherent light with a wavelength from about 250 nm to about 1050 nm.

44. The system according to claim 21, wherein said pulsed laser source emits coherent light with a wavelength of about 308 nm.

45. The system according to claim 21, wherein said pulsed laser source emits coherent light with a wavelength between about 490 nm and about 1040 nm.

46. The system according to claim 21, wherein said pulsed laser source emits coherent light with a wavelength between about 380 nm and about 760 nm.

47. The system according to claim 21, wherein said pulsed laser source emits coherent light with a wavelength of 760 nm.

48. The system according to claim 21, wherein said pulsed laser source emits two coherent light wavelengths of 380 nm and 760 nm, respectively.

49. The system according to claim 48, wherein a second pulsed laser source emits a coherent light beam with a wavelength of 308 nm and is combined with the coherent light beams with wavelengths of 380 nm and 760 nm.

50. The method of claim 1, wherein said plurality of wavelengths are in phase.

51. The method of claim 1, wherein said plurality of wavelengths are out of phase.

52. The system of claim 21, wherein said plurality of wavelengths are in phase.

53. The system of claim 21, wherein said plurality of wavelengths are out of phase.

54. The system of claim 21, further including a substrate for receiving a volatized solid organic or coordination complex substance for forming a layer of an OLED.

55. The method of claim 1, wherein a first laser source generates one coherent light wavelength, and a second laser source generates a second coherent light wavelength.

56. The method of claim 1, wherein said at least one pulsed laser source generates two coherent light wavelengths.

57. The system of claim 21, wherein a first laser source generates one coherent light wavelength, and a second laser source generates a second coherent light wavelength.

58. The system of claim 21, wherein said at least one pulsed laser source generates two coherent light wavelengths.
